(19) United States
(12) Patent Application Publication
(10) Pub. No.: US 2026/0080953 A1
(43) Pub. Date: Mar. 19, 2026

(54) NON-VOLATILE MEMORY DEVICE AND METHOD OF OPERATING THE SAME

(71) Applicant: Samsung Electronics Co., Ltd., Suwon-si (KR)

(72) Inventors: Eunhyang Park, Suwon-si (KR); Jin-Young Kim, Suwon-si (KR); Se Hwan Park, Suwon-si (KR)

(21) Appl. No.: 19/276,098

(22) Filed: Jul. 22, 2025

(30) Foreign Application Priority Data
Sep. 19, 2024 (KR) 10-2024-0126838

(51) Int. Cl. G11C 16/30; G11C 16/20; G11C 16/24; G11C 16/26

(52) U.S. Cl. CPC G11C 16/30; G11C 16/20; G11C 16/24; G11C 16/26

(57) ABSTRACT

A non-volatile memory device includes a memory cell array including a plurality of memory cells, and a control logic circuit configured to determine a read voltage for the plurality of memory cells through an on-chip valley search (OVS) operation on a distribution of threshold voltages of the plurality of memory cells. The control logic circuit may be configured to obtain a first estimated voltage through a first OVS operation on a first range of the distribution of threshold voltages, obtain a second estimated voltage through a second OVS operation on a second range of the distribution of threshold voltages, and obtain a third estimated voltage through a third OVS operation on a third range of the distribution of threshold voltages. The second range may be smaller than the first range, and the third range may be smaller than the second range.

### CROSS-REFERENCE TO RELATED APPLICATIONS

This U.S. non-provisional application claims priority under 35 U.S.C. § 119 to Korean Patent Application No. 10-2024-0126838, filed on Sep. 19, 2024, in the Korean Intellectual Property Office, the disclosure of which is herein incorporated by reference in its entirety.

### BACKGROUND OF THE INVENTION

Example embodiments relate to a non-volatile memory device and a method of operating the same.

A semiconductor memory device is a storage device that may be implemented using a semiconductor material such as silicon (Si), germanium (Ge), gallium arsenide (GaAs), and/or indium phosphide (InP). Semiconductor memory devices are broadly classified into volatile memory devices and non-volatile memory devices.

Volatile memory devices lose their stored data when their power supplies are interrupted, whereas non-volatile memory devices retain their stored data even when their power supplies are interrupted.

Characteristics of semiconductor memory devices may change due to various factors, such as the usage environment, frequency of use, and/or duration of use. Such changes may degrade the reliability of semiconductor memory devices. Accordingly, research into methods for improving the reliability of semiconductor memory devices is being conducted.

### SUMMARY OF THE INVENTION

Example embodiments provide a non-volatile memory device that improves the performance of an operation to determine a read voltage for a plurality of memory cells.

According to some example embodiments, a non-volatile memory device may include a memory cell array comprising a plurality of memory cells, and a control logic circuit configured to determine a read voltage for the plurality of memory cells through an on-chip valley search (OVS) operation on a distribution of threshold voltages of the plurality of memory cells. The control logic circuit may be configured to obtain a first estimated voltage through a first OVS operation on a first range of the distribution of threshold voltages, wherein the first range is relative to a default voltage, obtain a second estimated voltage through a second OVS operation on a second range of the distribution of threshold voltages in response to an absolute difference between the first estimated voltage and the default voltage being less than or equal to a first threshold value, wherein the second range is smaller than the first range and is relative to the first estimated voltage, and obtain a third estimated voltage through a third OVS operation on a third range of the distribution of threshold voltages in response to the absolute difference between the first estimated voltage and the default voltage being greater than the first threshold value, wherein the third range is smaller than the second range and is relative to the first estimated voltage.

According to some example embodiments, a method of operating a non-volatile memory device may include obtaining a first estimated voltage through a first on-chip valley search (OVS) operation on a first range of a distribution of threshold voltages of a plurality of memory cells, wherein the first range is relative to a default voltage, obtaining a second estimated voltage through a second OVS operation on a second range of the distribution of threshold voltages in response to an absolute difference between the first estimated voltage and the default voltage being less than or equal to a first threshold value, wherein the second range is smaller than the first range and is relative to the first estimated voltage, and obtaining a third estimated voltage through a third OVS operation on a third range of the distribution of threshold voltages in response to the absolute difference between the first estimated voltage and the default voltage being greater than the first threshold value, wherein the third range is smaller than the second range and is relative to the first estimated voltage.

According to some example embodiments, a memory system may include a memory device, and a memory controller configured to store data in the memory device and read data stored in the memory device. The memory device may include a memory cell array comprising a plurality of memory cells, and a control logic circuit configured to determine read voltages of the plurality of memory cells through an on-chip valley search (OVS) operation on a distribution of threshold voltages of the plurality of memory cells. The control logic circuit may be configured to obtain a first estimated voltage through a first OVS operation on a first range of the distribution of threshold voltages, wherein the first range is relative to a default voltage, obtain a second estimated voltage through a second OVS operation on a second range of the distribution of threshold voltages in response to an absolute difference between the first estimated voltage and the default voltage being less than or equal to a first threshold value, wherein the second range is smaller than the first range and is relative to the first estimated voltage, and obtain a third estimated voltage through a third OVS operation on a third range of the distribution of threshold voltages in response to the absolute difference between the first estimated voltage and the default voltage being greater than the first threshold value, wherein the third range is smaller than the second range and is relative to the first estimated voltage.

### BRIEF DESCRIPTION OF DRAWINGS

FIG. 1 is a block diagram of a non-volatile memory device according to some example embodiments.

FIG. 2 is a circuit diagram illustrating a single memory block among a plurality of memory blocks according to some example embodiments.

FIG. 3 is a diagram illustrating a configuration in which a control logic circuit performs a first OVS operation on a first range relative to a reference voltage.

FIG. 4A is a diagram illustrating a configuration in which the control logic circuit performs a second OVS operation on a second range relative to a first estimated voltage when a difference between the first estimated voltage and a default voltage is less than or equal to a first threshold value, according to some example embodiments.

FIG. 4B is a diagram illustrating a configuration in which the control logic circuit performs a third OVS operation on a third range relative to the first estimated voltage when a difference between the first estimated voltage and the default voltage is greater than a first threshold value, according to some example embodiments.

FIG. 5A is a block diagram of a non-volatile memory device according to some example embodiments.

FIG. 5B is a circuit diagram of a first page buffer in a first page buffer group according to some example embodiments.

FIG. 6 is a diagram illustrating control signals used by a control logic circuit to control a first page buffer and perform an OVS operation, according to some example embodiments.

FIG. 7A is a diagram illustrating a configuration in which a control logic circuit controls a first page buffer when a difference between a first estimated voltage and a default voltage is less than or equal to a first threshold value, according to some example embodiments.

FIG. 7B illustrates a configuration in which a control logic circuit controls a first page buffer when a difference between a first estimated voltage and a default voltage is greater than a first threshold value, according to some example embodiments.

FIG. 8A is a diagram illustrating a configuration in which a control logic circuit controls a first page buffer when a difference between a first estimated voltage and a default voltage is less than or equal to a second threshold value but is greater than a third threshold value, according to some example embodiments.

FIG. 8B is a diagram illustrating a configuration in which a control logic circuit controls a first page buffer when a difference between a first estimated voltage and a default voltage is less than or equal to a third threshold value, according to some example embodiments.

FIG. 9 is a flowchart illustrating a method of operating a non-volatile memory device according to some example embodiments.

FIG. 10 is a flowchart illustrating a method of obtaining a first estimated voltage by a control logic circuit according to some example embodiments.

FIG. 11 is a flowchart illustrating a method of obtaining a first cell count by a control logic circuit according to some example embodiments.

FIG. 12 is a flowchart illustrating a method of controlling a first page buffer to perform an OVS operation by a control logic circuit based on a magnitude of a difference between a first estimated voltage and a reference voltage, according to some example embodiments.

FIG. 13 is a block diagram illustrating a memory system including a memory controller and a memory device, according to some example embodiments.

### DETAILED DESCRIPTION

Hereinafter, example embodiments will be described with reference to the accompanying drawings.

The terms “first,” “second,” “third,” or the like used herein may modify various elements regardless of the order and/or priority thereof, and are used only for distinguishing one element from another element, without limiting example embodiments. For example, a first element could be termed a second element, and, similarly, a second element could be termed a first element, without departing from the scope of the present disclosure. As used herein, the terms “comprises,” “comprising,” “includes,” “including,” “has,” “having” and any other variations thereof specify the presence of the stated features, steps, operations, elements, components, and/or groups but do not preclude the presence or addition of one or more other features, steps, operations, elements, components, and/or groups thereof. Further, as used herein, the term “and/or” includes any and all combinations of one or more of the associated listed items.

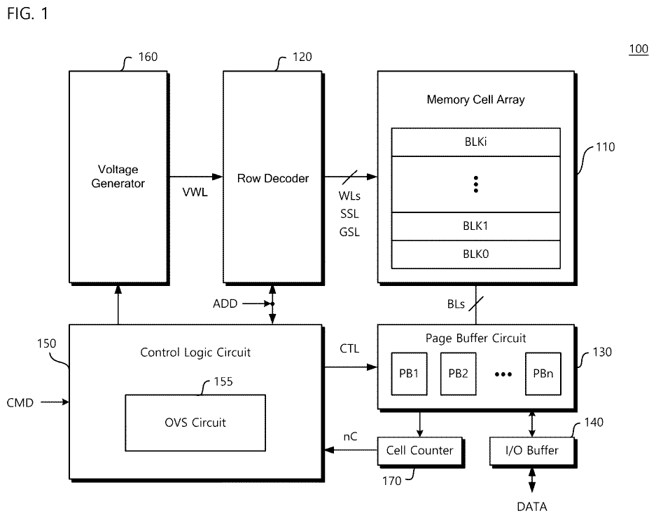

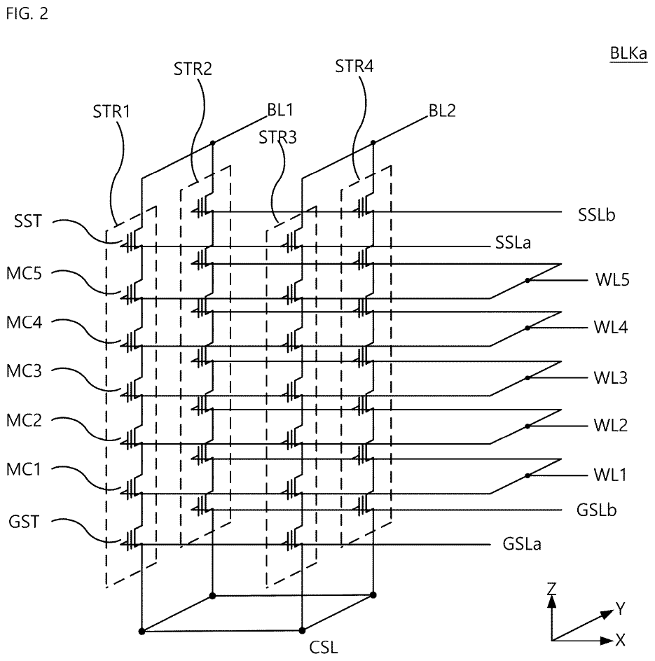

FIG. 1 is a block diagram of a non-volatile memory device according to some example embodiments. FIG. 2 is a circuit diagram illustrating a single memory block among a plurality of memory blocks according to some example embodiments.

Referring to FIG. 1, a non-volatile memory device 100 may include a memory cell array 110, a row decoder 120, a page buffer circuit 130, an input/output buffer circuit 140, a control logic circuit 150, a voltage generator 160, and a cell counter 170.

The non-volatile memory device 100 may be implemented to store data. For example, the non-volatile memory device 100 may be referred to as a NAND flash memory, a vertical NAND flash memory, a NOR flash memory, a resistive random access memory (RRAM), a phase-change memory (PRAM), a magnetoresistive random access memory (MRAM), a ferroelectric random access memory (FRAM), a spin-transfer torque random access memory (STT-RAM), or the like. In addition, the non-volatile memory device 100 may be implemented in a three-dimensional (3D) array structure. The non-volatile memory device 100 according to some example embodiments may be referred to as a flash memory device in which a charge storage layer includes a conductive floating gate, as well as a charge trap flash (CTF) memory device in which a charge storage layer includes an insulating layer. For ease of description, an example is provided in which the non-volatile memory device 100 is a vertical NAND flash memory device (VNAND), although example embodiments of the present disclosure are not limited thereto.

The non-volatile memory device 100 may include a memory cell array 110 including a plurality of memory cells. For example, the memory cell array 110 may include a plurality of memory blocks BLK0 to BLKi, each including a plurality of memory cells.

According to some example embodiments, the memory cell array 110 may be connected to the row decoder 120 through wordlines WLs or select lines SSL and GSL. Also, the memory cell array 110 may be connected to the page buffer circuit 130 through bitlines BLs.

The memory cell array 110 may include a plurality of cell strings. A channel of each of the cell strings may be formed in a vertical or horizontal direction. Also, the channel of each of the cell strings may include a plurality of memory cells.

According to some example embodiments, at least a portion of the plurality of memory cells may be programmed, erased, or read by a voltage supplied from the bitlines BLs or the wordlines WLs. In general, a program operation may be performed in units of page, and an erasing operation may be performed in units of blocks.

According to some example embodiments, the memory cell array 110 may include a two-dimensional (2D) memory cell array, and the two-dimensional memory cell array may include a plurality of NAND strings disposed in a row direction and a column direction.

According to some other example embodiments, the memory cell array 110 may include a three-dimensional (3D) memory cell array, and the three-dimensional memory cell array may include a plurality of NAND strings formed in a direction, perpendicular to a substrate.

According to some example embodiments, the row decoder 120 may be implemented to select one of the memory blocks BLK0 to BLKi of the memory cell array 110 in response to an address ADD. For example, the row decoder 120 may select a single wordline, among wordlines WLs of the selected memory block, in response to the address ADD.

In addition, the row decoder 120 may provide a wordline voltage VWL corresponding to an operation mode of the selected wordline. The row decoder 120 may apply a program voltage and a verify voltage to the selected wordline and apply a pass voltage to unselected wordlines, during a program operation. The row decoder 120 may apply a read voltage to the selected wordline and apply a read pass voltage to unselected wordlines, during a read operation.

The page buffer circuit 130 may be implemented to operate as a write driver or a sense amplifier.

For example, the page buffer circuit 130 may apply a bitline voltage corresponding to data to be programmed to at least a portion of the bitlines BLs of the memory cell array 110 during a program operation. For example, the page buffer circuit 130 may operate as a write driver during a program operation.

The page buffer circuit 130 may sense data, stored in a selected memory cell, through at least a portion of the bitlines BLs during a read operation or a verification read operation. For example, the page buffer circuit 130 may operate as a sense amplifier during a read operation.

According to some example embodiments, each of a plurality of page buffers PB1 to PBn (where n is an integer greater than or equal to 2) included in the page buffer circuit 130 may be connected to at least one bitline.

According to some example embodiments, each of the plurality of page buffers PB1 to PBn may be implemented to store state data of a plurality of memory cells to perform an on-chip valley search (OVS) operation.

For example, each of the plurality of page buffers PB1 to PBn may identify at least one state of selected memory cells under the control of the control logic circuit 150. Also, each of the plurality of page buffers PB1 to PBn may store the identified state data.

According to some example embodiments, the input/output buffer circuit 140 may provide data DATA, received from an external entity (i.e., an external device), to the page buffer circuit 130.

Also, the input/output buffer circuit 140 may provide a command CMD, received from an external entity, to the control logic circuit 150. Also, the input/output buffer circuit 140 may provide an address ADD, received from an external entity, to the control logic circuit 150 or the row decoder 120. Also, the input/output buffer circuit 140 may output data DATA, identified or stored by the page buffer circuit 130, to an external entity.

According to some example embodiments, the non-volatile memory device 100 may include a control logic circuit 150 implemented to control the row decoder 120 and the page buffer circuit 130 in response to the command CMD transmitted from the external entity.

The control logic circuit 150 may execute software (or a program) to control at least one other component (for example, the row decoder 120 and/or the page buffer circuit 130) of the non-volatile memory device 100, and perform various data processing or computations. The control logic circuit 150 may include a central processing unit (CPU) or a microprocessor, and may control the overall operation of the non-volatile memory device 100. Therefore, the operations performed by the non-volatile memory device 100 may be understood as being performed under the control of the control logic circuit 150.

According to some example embodiments, the control logic circuit 150 may include an on-chip valley search (OVS) circuit 155 to perform an OVS operation. For example, the operation performed by the OVS circuit 155 may be understood as being performed by the control logic circuit 150.

According to some example embodiments, the OVS circuit 155 (or the control logic circuit 150) may control the page buffer circuit 130 and the voltage generator 160 to perform the OVS operation.

For example, the OVS circuit 155 may control the page buffer circuit 130 to identify the state data of selected memory cells. Also, the OVS circuit 155 may control the plurality of page buffers PB1 to PBn to store the identified state data in latch circuits respectively provided in the plurality of page buffers PB1 to PBn.

The voltage generator 160 may generate a wordline voltage VWL to be applied to the wordlines WLs under the control of the control logic circuit 150. The wordline voltages, respectively applied to the wordlines WLs, may include a program voltage, a pass voltage, a read voltage, a read pass voltage, or the like.

The cell counter 170 may be implemented to count memory cells corresponding to a specific threshold voltage range from the data stored in the page buffer circuit 130.

For example, the cell counter 170 may count the number of memory cells having a threshold voltage within a specific range by processing the data stored in each of the plurality of page buffers PB1 to PBn.

The control logic circuit 150 (or the OVS circuit 155) according to some example embodiments may perform an OVS operation on a plurality of memory cells based on the count result nC of the cell counter 170.

For example, the control logic circuit 150 may perform a first OVS operation on a first range based on a predetermined reference voltage.

For example, the default voltage may be understood as a voltage set for a read operation during an initial program operation on a plurality of memory cells. For example, the default voltage may be understood as a voltage corresponding to a valley in a distribution of threshold voltages of a plurality of memory cells during an initial program operation on the memory cell array 110.

Also, the first range may be understood as a range between two voltage levels having a predetermined difference from the default voltage centered around the reference voltage. As used herein, “a range relative to a default voltage” (or similar language) may indicate that the range includes a span of threshold voltages, with the default voltage within the span. For example, the default voltage may be in the middle of the span of threshold voltages (i.e., the span of threshold voltages may be centered around the default voltage), but example embodiments are not limited thereto.

The control logic circuit 150 may determine the number of memory cells having a threshold voltage within the first range based on the count result nC.

In addition, the control logic circuit 150 may obtain (or determine) a first estimated voltage, which is estimated to be a valley in the distribution of the threshold voltages of the plurality of memory cells, based on the number of memory cells having a threshold voltage within the first range.

In addition, the control logic circuit 150 may perform an OVS operation based on the first estimated voltage obtained through the first OVS operation.

For example, the control logic circuit 150 may perform an additional OVS operation on a range smaller than the first range relative to the first estimated voltage. As used herein, “a second range smaller than a first range” (or similar language) may indicate that the second range includes fewer values than the first range and/or that the values included within the second range are smaller than (i.e., less than) the values included within the first range.

The range of the additionally performed OVS operation may be determined by the magnitude of a difference between the first estimated voltage and the reference voltage. As used herein, the difference between the first estimated voltage and the reference voltage (or default voltage) may refer to an absolute value of the difference (i.e., an absolute difference) between the first estimated voltage and the reference voltage.

For example, when the difference between the first estimated voltage and the default voltage is less than a predetermined first threshold value, the control logic circuit 150 may perform a second OVS operation on a second range smaller than the first range relative to the first estimated voltage. The control logic circuit 150 may obtain a second estimated voltage through the second OVS operation.

For example, when the difference between the first estimated voltage and the default voltage is greater than the first threshold value, the control logic circuit 150 may perform a third OVS operation on a third range smaller than the second range relative to the first estimated voltage. The control logic circuit 150 may obtain a third estimated voltage through the third OVS operation.

The control logic circuit 150 according to some example embodiments may store the difference between the first estimated voltage and the default voltage and the range of the OVS operation corresponding to the difference.

For example, the control logic circuit 150 may divide the difference between the first estimated voltage and the default voltage into a plurality of intervals, and store data including the range of the OVS operation corresponding to each of the intervals in the form of a table (for example, a lookup table).

In addition, the control logic circuit 150 may determine a read voltage for the memory cell array 110 based on the estimated voltage (for example, the second estimated voltage or the third estimated voltage) obtained through the plurality of OVS operations.

For example, the control logic circuit 150 may apply the estimated voltage (for example, the second estimated voltage or the third estimated voltage), obtained through the plurality of OVS operations, through at least a portion of the wordlines WLs during a read operation.

Referring to FIG. 2, the memory block BLKa may include a plurality of memory strings STR1 to STR4 connected between the bitlines BL1 and BL2 and a common source line CSL. For example, the memory block BLKa may correspond to one of the memory blocks BLK0 to BLKi of the memory cell array 110 (see FIG. 1).

Each of the plurality of memory strings STR1 to STR4 may include a string select transistor SST, a plurality of memory cells MC1 to MC5, and a ground select transistor GST. In FIG. 2, each of the plurality of memory strings STR1 to STR4 is illustrated as including five memory cells MC1 to MC5, but example embodiments are not limited thereto.

The string select transistor SST may be connected to a corresponding string select line SSLa and SSLb. The plurality of memory cells MC1 to MC5 may be connected to corresponding wordlines WL1 to WL5, respectively. A portion of the wordlines WL1 to WL5 may correspond to dummy wordlines.

The ground select transistor GST may be connected to corresponding ground select lines GSLa and GSLb. The string select transistor SST may be connected to corresponding bitlines BL1 and BL2, and the ground select transistor GST may be connected to a common source line CSL.

Wordlines at the same height (for example, the first wordlines WL1) may be commonly connected, and the ground select lines GSLa and GSLb and the string select lines SSLa and SSLb may each be separated. In FIG. 2, the memory block BLKa is illustrated as being connected to five wordlines WL1 to WL5 and two bitlines BL1 and BL2, but example embodiments are not limited thereto.

For example, the control logic circuit 150 (see FIG. 1) may apply the estimated voltage (for example, the second estimated voltage or the third estimated voltage), obtained through the plurality of OVS operations, to the memory cells (e.g., the first memory cells MC1) connected to the first wordline WL1 through the first wordline WL1 during a read operation.

Referring to the above-described configuration, the control logic circuit 150 may perform an OVS operation on a smaller range relative to the first estimated voltage, as the difference between the first estimated voltage and the default voltage increases, based on a result of the first OVS operation.

The difference between the first estimated voltage and the default voltage may be understood as indicating the extent to which the distribution of threshold voltages in a plurality of memory cells has degraded.

For example, the control logic circuit 150 may perform an additional OVS operation on a relatively smaller range as the distribution of the threshold voltages in the plurality of memory cells increases.

As a result, the non-volatile memory device 100 according to example embodiments may improve the accuracy of an operation to estimate a valley in the distribution.

For example, the non-volatile memory device 100 may improve the performance (for example, reliability) of an operation to determine a read voltage for a plurality of memory cells.

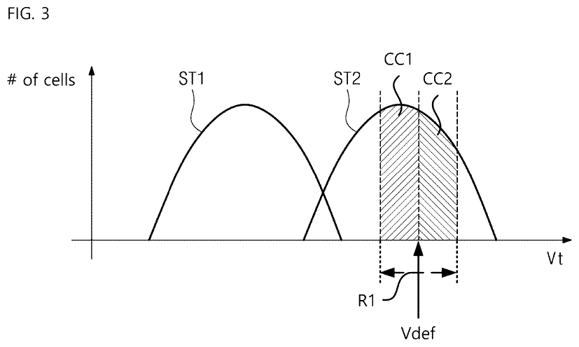

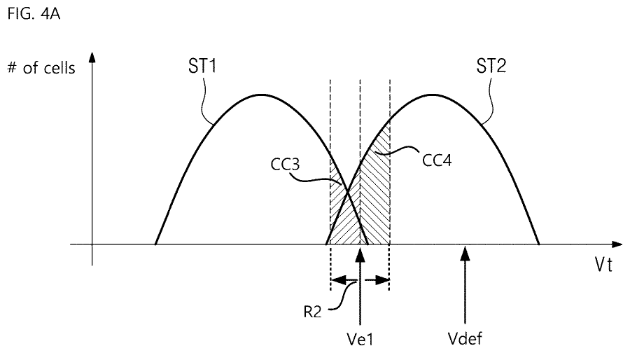

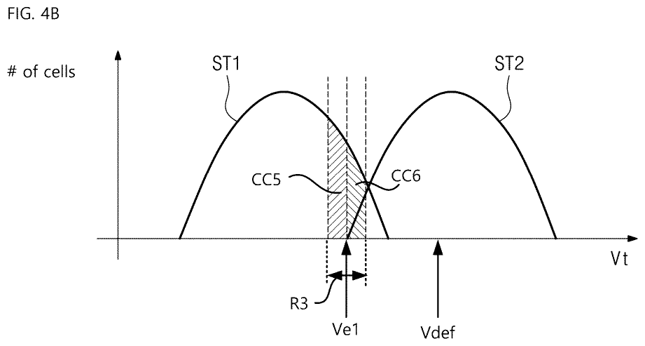

FIG. 3 is a diagram illustrating a configuration in which a control logic circuit performs a first OVS operation on a first range relative to a reference voltage. FIG. 4A is a diagram illustrating a configuration in which the control logic circuit performs a second OVS operation on a second range relative to a first estimated voltage when a difference between the first estimated voltage and a default voltage is less than or equal to a first threshold value, according to some example embodiments. FIG. 4B is a diagram illustrating a configuration in which the control logic circuit performs a third OVS operation on a third range relative to the first estimated voltage when a difference between the first estimated voltage and the default voltage is greater than a first threshold value, according to some example embodiments.

Referring to FIGS. 3, 4A, and 4B, the control logic circuit 150 (see FIG. 1) according to some example embodiments may obtain an estimated voltage estimated as a valley in the distributions of threshold voltages of a plurality of memory cells ST1 and ST2 through an OVS operation.

Referring to FIGS. 1 and 3, the control logic circuit 150 may perform a first OVS operation on a first range R1 based on a predetermined default voltage Vdef (which may also be referred to as a reference voltage).

For example, the default voltage Vdef may be understood as a voltage set for a read operation during an initial program operation on a plurality of memory cells. For example, the default voltage Vdef may be understood as a voltage corresponding to a valley, among distributions of threshold voltages of the plurality of memory cells, during an initial program operation on the memory cell array 110.

The first range R1 may be understood as a range between two voltage levels having a predetermined difference from the default voltage Vdef, centered around the default voltage Vdef. For example, the first range R1 may be a range within the distributions ST1 and ST2 of threshold voltages (Vt) of the plurality of memory cells and may be relative to the default voltage Vdef. In some embodiments, the first range R1 may be centered around the default voltage Vdef, but example embodiments are not limited thereto.

According to some example embodiments, the control logic circuit 150 may count the number of memory cells (# of cells) having a threshold voltage Vt within the first range R1 based on the default voltage Vdef using the cell counter 170.

For example, the control logic circuit 150 may count the number of memory cells having a threshold voltage Vt lower than or equal to the default voltage Vdef, among the memory cells having a threshold voltage Vt within the first range R1, to obtain a first cell count CC1.

In addition, the control logic circuit 150 may count the number of memory cells having a threshold voltage Vt higher than the default voltage Vdef, among the memory cells having a threshold voltage Vt within the first range R1, to obtain a second cell count CC2.

Furthermore, the control logic circuit 150 may obtain (or determine) a first estimated voltage Ve1 (e.g., see FIGS. 4A and 4B) estimated as a valley in the distributions ST1 and ST2 of the threshold voltages of a plurality of memory cells, based on the number of memory cells (# of cells) having a threshold voltage Vt within the first range R1.

For example, the control logic circuit 150 may obtain (or determine) the first estimated voltage Ve1 estimated as a valley in the distributions ST1 and ST2 of the threshold voltages of the plurality of memory cells based on a difference between the first cell count CC1 and the second cell count CC2.

According to some example embodiments, the control logic circuit 150 may obtain the first estimated voltage Ve1 from the first cell count CC1 and the second cell count CC2 based on a prestored equation (i.e., a predefined equation). The prestored equation may be referred to as Equation 1.

$$V e 1 = \frac{CC 1 - CC 2 - B}{A} \qquad Equation 1$$

where A and B may be understood as arbitrary coefficients. Therefore, information (or data) on values of A and B may be stored in the non-volatile memory device 100.

According to some example embodiments, the control logic circuit 150 may calculate a difference between the first estimated voltage Ve1 and the default voltage Vdef estimated as a valley in the distributions ST1 and ST2 of the threshold voltages of the plurality of memory cells based on the prestored equation.

The difference between the first estimated voltage Ve1 and the default voltage Vdef may be understood as indicating the extent to which the distributions ST1 and ST2 of the threshold voltages of the plurality of memory cells have moved due to the degradation of the plurality of memory cells.

For example, the control logic circuit 150 may perform a first OVS operation based on the predetermined default voltage Vdef and the first range R1 to obtain a first estimated voltage Ve1.

For example, the control logic circuit 150 according to some example embodiments may perform an OVS operation using a predetermined equation without storing a table corresponding to the extent to which the distribution of the threshold voltages of the memory cells has degraded.

As a result, the non-volatile memory device 100 according to example embodiments may improve the accuracy of the OVS operation relative to the case of storing a table corresponding to the extent to which the distribution of the threshold voltages of the memory cells has degraded.

Referring to FIGS. 1 and 4A, the control logic circuit 150 may perform a second OVS operation based on the first estimated voltage Ve1 obtained through the first OVS operation.

For example, the control logic circuit 150 may perform a second OVS operation on a second range R2 smaller than the first range R1 relative to the first estimated voltage Ve1. For example, the second range R2 may be a range within the distributions ST1 and ST2 of threshold voltages (Vt) of the plurality of memory cells and may be relative to the first estimated voltage Ve1. For example, the second range R2 may be centered around the first estimated voltage Ve1, but example embodiments are not limited thereto.

For example, when the difference between the first estimated voltage Ve1 and the default voltage Vdef is less than or equal to a predetermined first threshold value (for example, 300 mV), the control logic circuit 150 may perform a second OVS operation on a second range R2 smaller than the first range R1 relative to the first estimated voltage Ve1.

In addition, the control logic circuit 150 may obtain a second estimated voltage through the second OVS operation.

For example, the control logic circuit 150 may count the number of memory cells (# of cells) having a threshold voltage Vt lower than or equal to the first estimated voltage Ve1, among the memory cells having a threshold voltage Vt within the second range R2, based on the first estimated voltage Ve1 to obtain a third cell count CC3.

Also, the control logic circuit 150 may count the number of memory cells (# of cells) having a threshold voltage Vt higher than the first estimated voltage Ve1, among the memory cells having a threshold voltage Vt within the second range R2, based on the first estimated voltage Ve1 to obtain a fourth cell count CC4.

Furthermore, the control logic circuit 150 may compare the third cell count CC3 and the fourth cell count CC4 to obtain a second estimated voltage.

For example, the control logic circuit 150 may obtain the second estimated voltage based on a difference between the third cell count CC3 and the fourth cell count CC4.

For example, the control logic circuit 150 may obtain the second estimated voltage from the third cell count CC3 and the fourth cell count CC4 using Equation 1. For example, the control logic circuit 150 may obtain the second estimated voltage by replacing the first cell count CC1 in Equation 1 with the third cell count CC3 and replacing the second cell count CC2 in Equation 1 with the fourth cell count CC4.

Referring to FIGS. 1 and 4B, the control logic circuit 150 may perform a third OVS operation based on the first estimated voltage Ve1 obtained through the first OVS operation.

For example, the control logic circuit 150 may perform a third OVS operation on a third range R3 smaller than the second range R2 relative to the first estimated voltage Ve1. For example, the third range R3 may be a range within the distributions ST1 and ST2 of threshold voltages (Vt) of the plurality of memory cells and may be relative to the first estimated voltage Ve1. For example, the third range R3 may be centered around the first estimated voltage Ve1, but example embodiments are not limited thereto.

For example, when the difference between the first estimated voltage Ve1 and the default voltage Vdef is greater than a predetermined first threshold value, the control logic circuit 150 may perform a third OVS operation on a third range R3 smaller than the second range R2 relative to the first estimated voltage Ve1.

Also, the control logic circuit 150 may obtain a third estimated voltage through the third OVS operation.

For example, the control logic circuit 150 may count the number of memory cells (# of cells) having a threshold voltage Vt lower than or equal to the first estimated voltage Ve1, among the memory cells having a threshold voltage Vt within the third range R3, based on the first estimated voltage Ve1 to obtain a fifth cell count CC5.

Also, the control logic circuit 150 may count the number of memory cells (# of cells) having a threshold voltage Vt higher than the first estimated voltage Ve1, among the memory cells having a threshold voltage Vt within the third range R3, based on the first estimated voltage Ve1 to obtain a sixth cell count CC6.

Furthermore, the control logic circuit 150 may compare the fifth cell count CC5 and the sixth cell count CC6 to obtain a third estimated voltage. For example, the control logic circuit 150 may obtain the third estimated voltage based on a difference between the fifth cell count CC5 and the sixth cell count CC6.

For example, the control logic circuit 150 may obtain the third estimated voltage from the fifth cell count CC5 and the sixth cell count CC6 using Equation 1. For example, the control logic circuit 150 may obtain the third estimated voltage by replacing the first cell count CC1 in Equation 1 with the fifth cell count CC5 and replacing the second cell count CC2 in Equation 1 with the sixth cell count CC6.

Furthermore, the control logic circuit 150 may determine an estimated voltage (for example, the second estimated voltage or the third estimated voltage), obtained through a plurality of OVS operations, as a read voltage for the memory cell array 110.

For example, during a read operation, the control logic circuit 150 may apply the estimated voltage (for example, the second estimated voltage or the third estimated voltage), obtained through the plurality of OVS operations, through at least a portion of the wordlines WLs.

Referring to the above-described configuration, the control logic circuit 150 may perform an OVS operation on a smaller range relative to the first estimated voltage Ve1, as the difference between the first estimated voltage Ve1 and the default voltage Vdef increases, based on a result of the first OVS operation.

The difference between the first estimated voltage Ve1 and the default voltage Vdef may be understood as indicating the extent to which the distribution of threshold voltages of a plurality of memory cells has degraded.

For example, the control logic circuit 150 may perform an OVS operation on a relatively smaller range as the extent to which the threshold voltage distribution of a plurality of memory cells has degraded increases.

As a result, the non-volatile memory device 100 according to example embodiments may improve the accuracy of an operation to estimate a valley in the distribution. For example, the non-volatile memory device 100 may improve the performance of an operation to determine a read voltage for a plurality of memory cells.

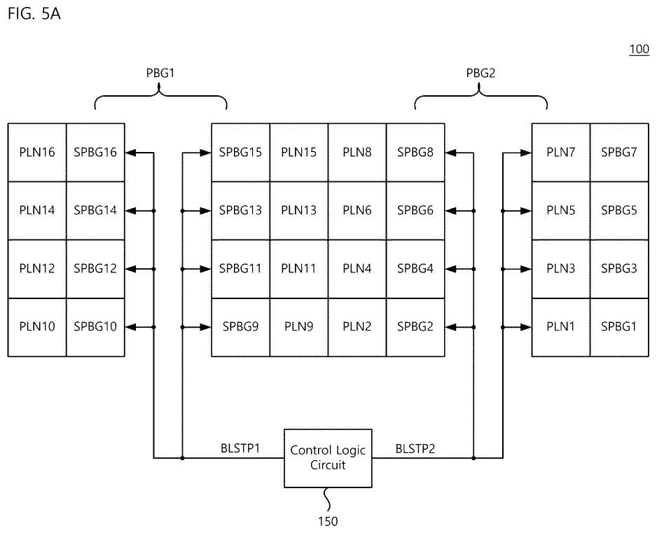

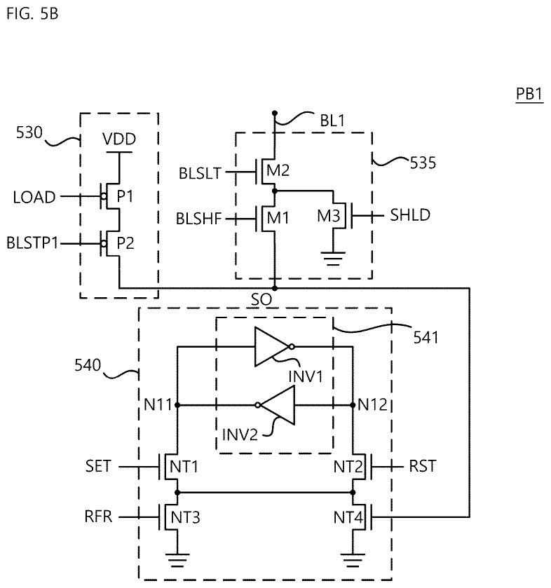

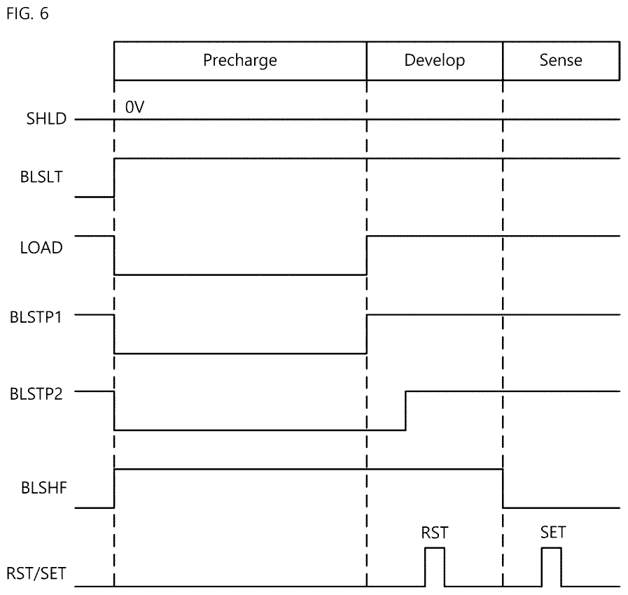

FIG. 5A is a block diagram of a non-volatile memory device according to some example embodiments. FIG. 5B is a circuit diagram of a first page buffer in a first page buffer group according to some example embodiments. FIG. 6 is a diagram illustrating control signals used by a control logic circuit to control a first page buffer and perform an OVS operation, according to some example embodiments.

Referring to FIGS. 1 and 5A, a non-volatile memory device 100 according to some example embodiments may include a memory cell array 110 and a page buffer circuit 130.

The memory cell array 110 may include a plurality of planes PLN1 to PLN16. Also, the page buffer circuit 130 may include a plurality of sub-page buffer groups SPBG1 to SPBG16 corresponding to the plurality of planes PLN1 to PLN16.

The page buffers included in the sub-page buffer groups SPBG9 to SPBG16 may constitute a first page buffer group PBG1, and the page buffers included in the sub-page buffer groups SPBG1 to SPBG8 may constitute a second page buffer group PBG2.

While a total of 16 sub-page buffer groups SPBG1 to SPBG16 have been described as constituting two page buffer groups PBG1 and PBG2, the configuration of the page buffer circuit 130 is not limited to the above example.

According to some example embodiments, the page buffer circuit 130 may include a total of N sub-page buffer groups (where N is an arbitrary positive integer), which constitute M page buffer groups (where M is an arbitrary positive integer).

According to some example embodiments, the control logic circuit 150 may apply a first bitline set-up signal BLSTP1 to the first page buffer group PBG1 to develop a bitline (for example, a first bitline BL1) connected to the page buffers included in the first page buffer group PBG1.

Also, the control logic circuit 150 may apply a second bitline set-up signal BLSTP2 to the second page buffer group PBG2 to develop a bitline (for example, a second bitline BL2) connected to the page buffers included in the second page buffer group PBG2.

Referring to FIG. 5B, the first page buffer PB1 according to some example embodiments may include a precharge circuit 530, a switch circuit 535, and a latch circuit 540.

The first page buffer PB1 may be understood as a page buffer included in the first page buffer group PBG1 of FIG. 5A.

The precharge circuit 530 may include a first PMOS transistor P1 and a second PMOS transistor P2 connected in series between a power supply voltage VDD and a sense node SO.

The first PMOS transistor P1 may be turned on or off in response to a load signal LOAD, and the second PMOS transistor P2 may be turned on or off in response to the first bitline set-up signal BLSTP1.

The switch circuit 535 may include a plurality of transistors M1, M2, and M3.

The first transistor M1 may be turned on or off in response to a bitline voltage control signal BLSHF. Also, the second transistor M2 may be turned on or off in response to a bitline select signal BLSLT, and the third transistor M3 may be turned on or off in response to a shield signal SHLD.

Referring to FIGS. 1 and 5B, the precharge circuit 530, the switch circuit 535, and the latch circuit 540 may operate in response to a control signal CTL of the control logic circuit 150.

For example, referring to FIGS. 5B and 6, the control signal CTL may include a load signal LOAD, a first bitline set-up signal BLSTP1, a bitline voltage control signal BLSHF, a bitline select signal BLSLT, a shield signal SHLD, and a refresh signal RFR.

Still referring to FIGS. 5B and 6, the first PMOS transistor P1 and the second PMOS transistor P2 may be turned on by a low-level (e.g., having a logic value of ‘0’) load signal LOAD and a first bitline set-up signal BLSTP1 during a precharge period.

Accordingly, a voltage at the sense node SO may be precharged to the power supply voltage VDD during the precharge period.

According to some example embodiments, the second PMOS transistor P2 may be turned off by a high-level (e.g., having a logic value of ‘1’) first bitline set-up signal BLSTP1. For example, a develop period may be initiated (or started) in response to the first bitline set-up signal BLSTP1 transitioning to a high level.

According to some example embodiments, the first PMOS transistor P1 and the second PMOS transistor P2 may be turned off by the high-level load signal LOAD and the first bitline set-up signal BLSTP1 during the develop period. Accordingly, the sense node SO may be isolated from the power supply voltage VDD during the develop period.

Also, the first transistor M1 and the second transistor M2 may be turned on by a high-level bitline voltage control signal BLSHF and a bitline select signal BLSLT during the develop period.

Accordingly, a voltage precharged at the sense node SO may be discharged through the first bitline BL1 during the develop period.

The latch circuit 540 may detect a voltage level at the sense node SO. The latch circuit 540 may obtain state data (e.g., may store state data) of memory cells connected to the first bitline BL1 based on the detected voltage level at the sense node SO. For example, the latch circuit 540 may be connected (e.g., electrically connected) to the sense node SO.

The latch circuit 540 may include a latch 541 and a plurality of NMOS transistors NT1 to NT4.

The latch 541 may include inverters INV1 and INV2. Also, the first NMOS transistor NT1 and the third NMOS transistor NT3 may be connected in series between a first node N11 and a ground voltage. Also, the second NMOS transistor NT2 and the fourth NMOS transistor NT4 may be connected in series between a second node N12 and a ground voltage.

The first NMOS transistor NT1 may be controlled by a set signal SET applied to a gate electrode (or gate terminal) of the first NMOS transistor NT1. The second NMOS transistor NT2 may be controlled by a reset signal RST applied to a gate electrode (or gate terminal) of the second NMOS transistor NT2. The third NMOS transistor NT3 may be controlled by a refresh signal RFR applied to a gate electrode (or gate terminal) of the third NMOS transistor NT3. A gate electrode (or gate terminal) of the fourth NMOS transistor NT4 may be connected to the sense node SO. The latch circuit 540 may operate in response to control signals SET, RST, and RFR included in the control signal CTL.

For example, the latch circuit 540 may detect the voltage level at the sense node SO in response to the reset signal RST being applied within the develop period. For example, the latch circuit 540 may store first state data of memory cells connected to the first bitline BL1 in response to the reset signal RST being applied (e.g., in response to the reset signal RST having a high logic level).

Also, the latch circuit 540 may detect the voltage level at the sense node SO in response to the set signal SET being applied within the sensing period (i.e., sense period). For example, the latch circuit 540 may store second state data of the memory cells connected to the first bitline BL1 in response to the set signal SET being applied (e.g., in response to the set signal SET having a high logic level).

Furthermore, the control logic circuit 150 may count the number of memory cells having a threshold voltage within a specified range, based on the state data stored in the latch circuit 540.

For example, the control logic circuit 150 may count the number of memory cells having a threshold voltage within a range corresponding to the difference between the reset signal RST and the set signal SET, based on the first state data and the second state data.

The first state data may be understood to include data related to the operational states (for example, an ON state or an OFF state) of each memory cell connected to the first bitline BL1 at a time point at which a reset signal RST is applied to the latch circuit 540.

In addition, the second state data may be understood to include data related to an operating state of each of the memory cells connected to the first bitline BL1 at a time point at which the set signal SET is applied to the latch circuit 540.

For example, the control logic circuit 150 may perform an exclusive OR (XOR) operation between the first state data and the second state data to count the number of memory cells having a threshold voltage within a range corresponding to the difference between the reset signal RST and the set signal SET.

The above-described configuration may allow the control logic circuit 150 to count the number of memory cells having a threshold voltage within a designated range.

For example, the control logic circuit 150 may count the number of memory cells having a threshold voltage within a specified range by controlling the first page buffer PB1 to perform an operation including a precharge period, a develop period, and a sensing period.

Also, the control logic circuit 150 may count the number of memory cells having a threshold voltage within a designated range by controlling a second page buffer PB2 (e.g., see FIG. 1) to perform operations including a precharge period, a develop period, and a sensing period.

The second page buffer PB2 may be understood as having substantially the same configuration as the first page buffer PB1. Also, the second page buffer PB2 may be understood as being included in the second page buffer group PBG2 of FIG. 5A.

For example, the develop period of the second page buffer PB2 may be initiated when the second bitline set-up signal BLSTP2, different from the first bitline set-up signal BLSTP1, transitions to a high level.

For example, at least a portion of the operations of the first page buffer PB1 and the second page buffer PB2 may be simultaneously performed.

Furthermore, the control logic circuit 150 may perform a first OVS operation on a first range R1 based on a count result nC and a default voltage Vdef (e.g., see FIGS. 1 and 3).

For example, the control logic circuit 150 may control the page buffers PB1 and PB2 to determine the number of memory cells (# of cells) having a threshold voltage Vt within the first range R1 based on the default voltage Vdef and the number of memory cells counted.

Furthermore, the control logic circuit 150 may obtain (or determine) a first estimated voltage Ve1 (e.g., see FIGS. 4A and 4B) estimated as a valley in the distributions ST1 and ST2 of the threshold voltages of a plurality of memory cells, based on the number of memory cells (# of cells) having a threshold voltage Vt within the first range R1.

Also, the control logic circuit 150 may perform an additional OVS operation based on the first estimated voltage Ve1.

For example, the control logic circuit 150 may perform an additional OVS operation on a range smaller than the first range R1 relative to the first estimated voltage Ve1.

For example, when a difference between the first estimated voltage Ve1 and the default voltage Vdef is smaller than or equal to a predetermined first threshold value, the control logic circuit 150 may perform a second OVS operation on a second range R2 smaller than the first range R1 relative to the first estimated voltage Ve1 (see FIG. 4A). The control logic circuit 150 may obtain a second estimated voltage through the second OVS operation.

For example, when the difference between the first estimated voltage Ve1 and the default voltage Vdef is greater than the predetermined first threshold value, the control logic circuit 150 may perform a third OVS operation on a third range R3 smaller than the second range R2 relative to the first estimated voltage Ve1 (see FIG. 4B). The control logic circuit 150 may obtain a third estimated voltage through the third OVS operation.

Furthermore, the control logic circuit 150 may determine an estimated voltage (for example, a second estimated voltage or a third estimated voltage), obtained through a plurality of OVS operations, as a read voltage for the memory cell array 110. For example, the control logic circuit 150 may apply the estimated voltage (for example, the second estimated voltage or the third estimated voltage), obtained through the plurality of OVS operations, through at least a portion of the wordlines WLs.

Referring to the above-described configuration, the control logic circuit 150 may perform an OVS operation on a smaller range relative to the first estimated voltage Ve1, as a difference between the first estimated voltage Ve1 and the default voltage Vdef increases, based on a result of the first OVS operation.

The difference between the first estimated voltage Ve1 and the default voltage Vdef may be understood as indicating the extent to which the distribution of a plurality of memory cells has degraded.

For example, the control logic circuit 150 may perform an additional OVS operation on a relatively smaller range as the extent to which the distribution of the threshold voltages of the plurality of memory cells has degraded increases.

As a result, the non-volatile memory device 100 according to example embodiments may improve the accuracy of an operation to estimate a valley in the distribution. For example, the non-volatile memory device 100 may improve the performance of the operation (for example, may improve the reliability of an operation to determine a read voltage for the plurality of memory cells).

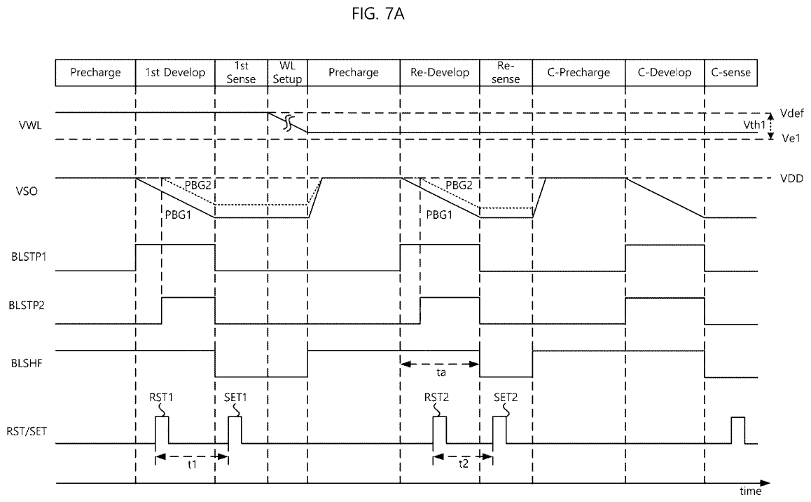

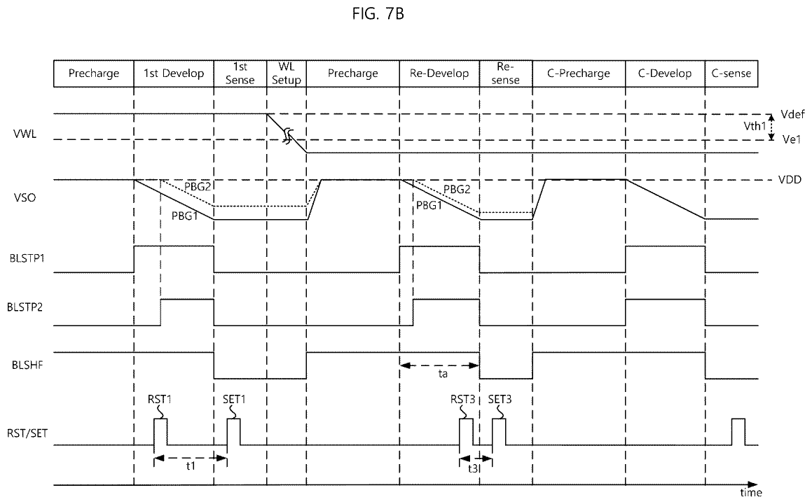

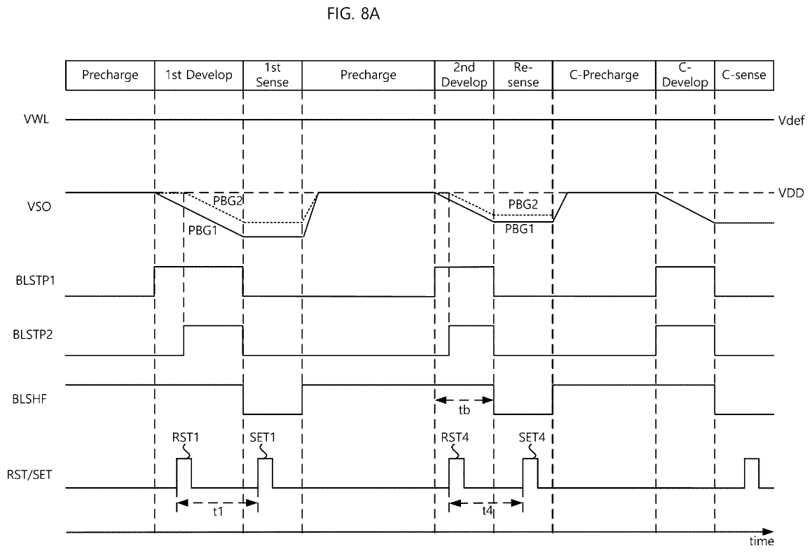

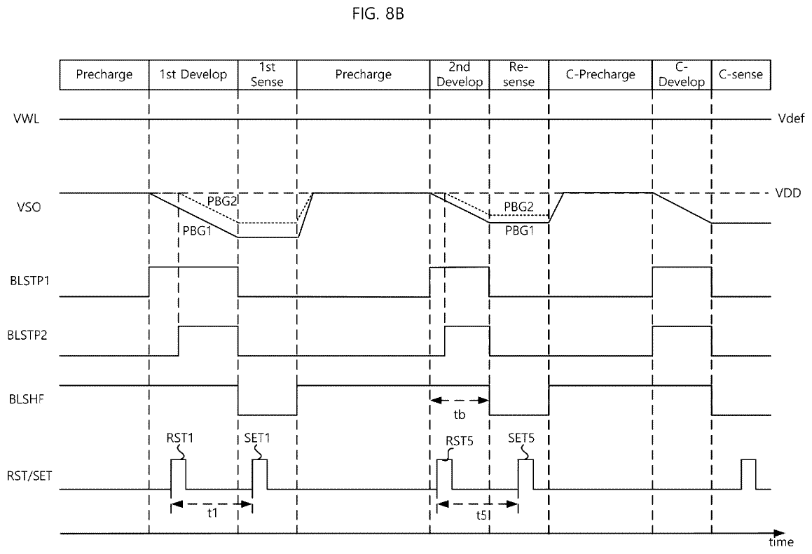

FIG. 7A is a diagram illustrating a configuration in which a control logic circuit controls a first page buffer when a difference between a first estimated voltage and a default voltage is less than or equal to a first threshold value (e.g., but is greater than a second threshold value), according to some example embodiments. FIG. 7B illustrates a configuration in which a control logic circuit controls a first page buffer when a difference between a first estimated voltage and a default voltage is greater than a first threshold value, according to some example embodiments. FIG. 8A is a diagram illustrating a configuration in which a control logic circuit controls a first page buffer when a difference between a first estimated voltage and a default voltage is less than or equal to a second threshold value but is greater than a third threshold value, according to some example embodiments. FIG. 8B is a diagram illustrating a configuration in which a control logic circuit controls a first page buffer when a difference between a first estimated voltage and a default voltage is less than or equal to a third threshold value, according to some example embodiments.

Referring to FIGS. 1, 7A, and 7B, the control logic circuit 150 according to some example embodiments may perform an additional OVS operation based on a first estimated voltage Ve1 when a difference between the first estimated voltage Ve1 and a default voltage Vdef, obtained through a first OVS operation, is greater than a second threshold value.

The second threshold value may be understood as being smaller than (i.e., less than) a first threshold value Vth1.

For example, the second threshold value may be 200 mV and the first threshold value may be 300 mV. However, these are merely examples and the threshold values are not limited thereto.

The control logic circuit 150 may perform a first OVS operation on a first range R1 based on a predetermined default voltage Vdef (e.g., see FIG. 3).

The control logic circuit 150 may precharge a sensing voltage VSO at a sense node SO to a power supply voltage VDD (e.g., see FIG. 5B).

For example, the control logic circuit 150 may control at least one transistor (for example, a first PMOS transistor P1) connected to the sense node SO to precharge a sensing voltage VSO to the power supply voltage VDD during a precharge period.

For example, the control logic circuit 150 may apply a low-level load signal LOAD to the first PMOS transistor P1 to turn on the first PMOS transistor P1 (e.g., see FIGS. 5B and 6). Thus, the control logic circuit 150 may connect the sense node SO to the power supply voltage VDD to precharge the sense node SO.

Furthermore, the control logic circuit 150 may perform a develop operation during a first develop period (i.e., a 1st develop period).

The control logic circuit 150 may apply a high-level first bitline set-up signal BLSTP1 to a first page buffer group PBG1 to initiate the first develop period. For example, the control logic circuit 150 may apply a high-level first bitline set-up signal BLSTP1 to the first page buffer group PBG1 during the first develop period.

For example, the control logic circuit 150 may develop the first bitline BL1 during the first develop period (e.g., see FIG. 5B). For example, the control logic circuit 150 may control the first page buffer PB1 to develop the first bitline BL1 during the first develop period.

For example, the control logic circuit 150 may control at least one transistor (for example, a first transistor M1) connected to the sense node SO such that the sensing voltage VSO, precharged to the power supply voltage VDD, is discharged through the first bitline BL1 during the first develop period (e.g., see FIG. 5B).

Also, the control logic circuit 150 may apply a high-level second bitline set-up signal BLSTP2 to the second page buffer group PBG2 during a develop period smaller than (i.e., shorter than) the first develop period. Thus, the control logic circuit 150 may develop the second bitline BL2 (e.g., see FIG. 2).

For example, the control logic circuit 150 may apply a second bitline set-up signal BLSTP2 to at least one transistor connected to the sense node SO such that the sensing voltage VSO, precharged to the power supply voltage VDD, is discharged through the second bitline BL2 during a develop period smaller than the first develop period (e.g., see FIGS. 2 and 5B).

The control logic circuit 150 according to some example embodiments may apply a first reset signal RST1 to the latch circuit 540 or the first page buffer PB1 within the first develop period such that the latch circuit 540 (or the first page buffer PB1) stores first state data of the memory cells connected to the first bitline BL1 (e.g., see FIG. 5B).

The control logic circuit 150 may apply a first set signal SET1 to the latch circuit 540 (or the first page buffer PB1) such that the latch circuit 540 (or the first page buffer PB1) stores second state data of the memory cells connected to the first bitline BL1 (e.g., see FIG. 5B).

The control logic circuit 150 may apply a first set signal SET1 to the latch circuit 540 after a first time t1 from a time point at which a first reset signal RST1 is applied to the latch circuit 540.

For example, the first time t1 may be understood as having a value corresponding to half of the first range R1.

The control logic circuit 150 may count the number of memory cells (for example, the first cell count CC1) having a threshold voltage within a range corresponding to the first time t1, based on the first state data and the second state data.

For example, the control logic circuit 150 may obtain the first cell count CC1 corresponding to the number of memory cells (# of cells) having a threshold voltage Vt, lower than or equal to the default voltage Vdef, in the first range R1 based on the first state data and the second state data (e.g., see FIG. 3).

In addition, the control logic circuit 150 may perform an operation, which is substantially the same as the operation to obtain the first cell count CC1, to obtain a second cell count CC2 (e.g., see FIG. 3).

For example, the control logic circuit 150 may apply a reset signal and a set signal having an interval of the first time t1 to the latch circuit 540. For example, the reset signal and the set signal may be output in synchronization with a rising edge of a clock signal, which is different from a rising edge at a time point at which the first reset signal RST1 and the first set signal SET1 are applied, in the clock signal.

As a result, the control logic circuit 150 may obtain the second cell count CC2 corresponding to the number of memory cells (# of cells) having a threshold voltage Vt, higher than the default voltage Vdef, in the first range R1 (e.g., see FIG. 3).

Furthermore, the control logic circuit 150 may obtain (or determine) the first estimated voltage Ve1 estimated as a valley in the distribution of the threshold voltages of the plurality of memory cells, based on the first cell count CC1 and the second cell count CC2 (e.g., see FIGS. 3, 4A, and 4B).

According to some example embodiments, the control logic circuit 150 may change a wordline voltage VWL to perform an OVS operation when the difference between the first estimated voltage Ve1 and the default voltage Vdef is greater than the second threshold value.

For example, the control logic circuit 150 may change the wordline voltage VWL to the first estimated voltage Ve1 when the difference between the first estimated voltage Ve1 and the default voltage Vdef is greater than the second threshold value.

For example, the control logic circuit 150 may control the voltage generator 160 to change the wordline voltage VWL to the first estimated voltage Ve1 during a wordline set-up period (i.e., a WL setup period) when the difference between the first estimated voltage Ve1 and the default voltage Vdef is greater than the second threshold value.

The wordline set-up period may be referred to as being longer than the first sensing period (i.e., the 1st sense period).

Furthermore, the control logic circuit 150 may apply the first estimated voltage Ve1 to a plurality of memory cells through at least a portion of the wordlines WLs.

For example, the control logic circuit 150 may perform an additional OVS operation relative to the first estimated voltage Ve1 when the difference between the first estimated voltage Ve1 and the default voltage Vdef is greater than the second threshold value.

For example, the control logic circuit 150 may precharge the sensing voltage VSO at the sense node SO to the power supply voltage VDD in response to the wordline set-up period coming to an end.

For example, the control logic circuit 150 may control at least one transistor (for example, the first PMOS transistor P1) connected to the sense node SO to precharge the sensing voltage VSO to the power supply voltage VDD during the precharge period (e.g., see FIG. 5B).

For example, the control logic circuit 150 may apply a low-level load signal LOAD to the first PMOS transistor P1 to turn on the first PMOS transistor P1 (e.g., see FIGS. 5B and 6). Thus, the control logic circuit 150 may connect the sense node SO to the power supply voltage VDD to precharge the sense node SO. In other words, the control logic circuit 150 may precharge the first bitline BL1 to the power supply voltage VDD.

Furthermore, the control logic circuit 150 may perform a develop operation during a re-develop period. The control logic circuit 150 may apply a high-level first bitline set-up signal BLSTP1 to the first page buffer group PBG1 during the re-develop period.

The re-develop period may be maintained for a first develop time ta corresponding to the first develop period.

For example, the control logic circuit 150 may develop the first bitline BL1 during the re-develop period corresponding to the first develop period (e.g., see FIG. 5B).

The re-develop period may be understood as having substantially the same time (e.g., a first develop time ta) as the first develop period.

For example, the control logic circuit 150 may control at least one transistor (for example, the first transistor M1) connected to the sense node SO such that the sensing voltage VSO, precharged to the power supply voltage VDD, is discharged through the first bitline BL1 during the re-develop period (e.g., see FIG. 5B).

Also, the control logic circuit 150 may apply a high-level second bitline set-up signal BLSTP2 to the second page buffer group PBG2 during a develop period smaller than the re-develop period. Thus, the control logic circuit 150 may develop the second bitline BL2 (e.g., see FIG. 2).

For example, the control logic circuit 150 may apply a second bitline set-up signal BLSTP2 to at least one transistor connected to the sense node SO such that the sensing voltage VSO, precharged to the power supply voltage VDD, is discharged through the second bitline BL2 during a develop period smaller than the re-develop period (e.g., see FIGS. 2 and 5B).

Referring to FIG. 7A, when the difference between the first estimated voltage Ve1 and the default voltage Vdef is less than or equal to the first threshold value Vth1, the control logic circuit 150 may apply a second reset signal RST2 to the latch circuit 540 within the re-develop period (e.g., see FIG. 5B).

For example, when the difference between the first estimated voltage Ve1 and the default voltage Vdef is less than or equal to the first threshold value Vth1, the control logic circuit 150 may apply a second reset signal RST2 to the first page buffer group PBG1 within the re-develop period.

Also, the control logic circuit 150 may apply the second reset signal RST2 to the second page buffer group PBG2 within the develop period smaller than the re-develop period.

The control logic circuit 150 may apply a second set signal SET2 to the latch circuit 540 after a second time t2 from a time point at which the second reset signal RST2 is applied (e.g., see FIG. 5B).

For example, the second time t2 may be understood as having a value corresponding to half of the second range R2.

The control logic circuit 150 may apply a second set signal SET2 to the latch circuit 540 within the first sensing period (i.e., a re-sense period), after a second time t2 from a time point at which the second reset signal RST2 is applied.

The control logic circuit 150 may count the number of memory cells having a threshold voltage within a range corresponding to the second time t2 based on the state data stored at a time point at which each of the second reset signal RST2 and the second set signal SET2 is applied.

For example, the control logic circuit 150 may obtain a third cell count CC3 corresponding to the number of memory cells (# of cells) having a threshold voltage Vt, lower than or equal to the first estimated voltage Ve1, in the second range R2 based on the state data stored at the time point at which each of the second reset signal RST2 and the second set signal SET2 is applied (e.g., see FIG. 4A).

In addition, the control logic circuit 150 may perform an operation, which is substantially the same as the operation to obtain the third cell count CC3, to obtain a fourth cell count CC4 (e.g., see FIG. 4A).

For example, the control logic circuit 150 may apply a reset signal and a set signal having an interval of a second time t2 to the latch circuit 540. For example, the reset signal and the set signal may be output to in synchronization with a rising edge of a clock signal, which is different from a rising edge at a time point at which the second reset signal RST2 and the second set signal SET2 are applied, in the clock signal.

As a result, the control logic circuit 150 may obtain the fourth cell count CC4 corresponding to the number of memory cells (# of cells) having a threshold voltage Vt higher than the first estimated voltage Ve1 in the second range R2 (e.g., see FIG. 4A).

Furthermore, the control logic circuit 150 may obtain (or determine) the second estimated voltage estimated as a valley in the distribution of the threshold voltages of a plurality of memory cells, based on the third cell count CC3 and the fourth cell count CC4.

Furthermore, the control logic circuit 150 may perform a compensation operation based on a result of the second OVS operation to determine the second estimated voltage.

For example, the control logic circuit 150 may perform an operation including a compensation-precharge period (i.e., a C-Precharge period), a compensation-develop period (i.e., a C-Develop period), and a compensation-sense period (i.e., a C-Sense period) based on a result of the second OVS operation.

For example, the control logic circuit 150 may control at least one transistor (for example, the first PMOS transistor P1) connected to the sense node SO to precharge the sensing voltage VSO to a power supply voltage VDD during the compensation-precharge period (C-precharge period) (e.g., see FIG. 5B).

Also, the control logic circuit 150 may perform a develop operation on the first bitline BL1 during the compensation-develop period (C-develop period) having a length corresponding to the second estimated voltage determined through the second OVS operation.

Also, the control logic circuit 150 may apply the set signal to the latch circuit 540 within the compensation-sense period (C-sense period) such that the latch circuit 540 stores state data.

Referring to FIG. 7B, when a difference between the first estimated voltage Ve1 and the default voltage Vdef is greater than the first threshold value Vth1, the control logic circuit 150 may apply a third reset signal RST3 to the latch circuit 540 within the re-develop period (e.g., see FIG. 5B).

For example, when the difference between the first estimated voltage Ve1 and the default voltage Vdef is greater than the first threshold value Vth1, the control logic circuit 150 may apply a third reset signal RST3 to the first page buffer group PBG1 within the re-develop period. Also, the control logic circuit 150 may apply the third reset signal RST3 to the second page buffer group PBG2 within a develop period smaller than the re-develop period.

However, the re-develop period illustrated in FIG. 7B may be relatively longer compared to the re-develop period illustrated in FIG. 7A. For example, the greater the difference between the first estimated voltage Ve1 and the default voltage Vdef, the longer the bitline may be developed.

The control logic circuit 150 may apply a third set signal SET3 to the latch circuit 540 after a third time t3 from a time point at which the third reset signal RST3 is applied.

For example, the third time t3 may be understood as having a value corresponding to half of the third range R3 smaller than the second range R2.

The control logic circuit 150 may count the number of memory cells having a threshold voltage within a range corresponding to the third time t3 based on the state data stored at a time point at which each of the third reset signal RST3 and the third set signal SET3 is applied.

For example, the control logic circuit 150 may obtain the fifth cell count CC5 corresponding to the number of memory cells (# of cells) having a threshold voltage Vt, lower than or equal to the first estimated voltage Ve1, in the third range R3 based on the state data stored at the time point at which each of the third reset signal RST3 and the third set signal SET3 is applied (e.g., see FIG. 4B).

In addition, the control logic circuit 150 may perform an operation, which is substantially the same as the operation to obtain the fifth cell count CC5, to obtain a sixth cell count CC6 (e.g., see FIG. 4B).

For example, the control logic circuit 150 may apply a reset signal and a set signal having an interval of a third time t3 to the latch circuit 540. For example, the reset signal and the set signal may be output in synchronization with a rising edge of the clock signal, which is different from the rising edge at a time point at which the third reset signal RST3 and the third set signal SET3 are applied, in the clock signal.

As a result, the control logic circuit 150 may obtain the sixth cell count CC6 corresponding to the number of memory cells (# of cells) having a threshold voltage Vt, higher than the first estimated voltage Ve1, in the third range R3 (e.g., see FIG. 4B).

Furthermore, the control logic circuit 150 may obtain (or determine) the third estimated voltage estimated as a valley in the distribution of the threshold voltages of a plurality of memory cells, based on the fifth cell count CC5 and the sixth cell count CC6.

Furthermore, the control logic circuit 150 may perform a compensation operation based on a result of the third OVS operation to determine the third estimated voltage.

For example, the control logic circuit 150 may perform an operation including a compensation-precharge period (C-Precharge period), a compensation-develop period (C-Develop period), and a compensation-sense period (C-Sense period) based on the result of the third OVS operation.

For example, the control logic circuit 150 may control at least one transistor (for example, the first PMOS transistor P1) connected to the sense node SO to precharge the sensing voltage VSO to the power supply voltage VDD during the compensation-precharge period (C-precharge period) (e.g., see FIG. 5B).

Also, the control logic circuit 150 may perform a develop operation on the first bitline BL1 during a compensation-develop period (C-develop period) corresponding to the length of the third estimated voltage determined through the third OVS operation.

Also, the control logic circuit 150 may apply the set signal to the latch circuit 540 within the compensation-sense period (C-sense period0 such that the latch circuit 540 stores state data.

Referring to the above-described configuration, the control logic circuit 150 may perform an OVS operation on a smaller range (for example, the third range R3) relative to the first estimated voltage Ve1, as the difference between the first estimated voltage Ve1 and the default voltage Vdef increases, based on the result of the first OVS operation.

The difference between the first estimated voltage Ve1 and the default voltage Vdef may be understood as corresponding to the extent to which the distribution of the threshold voltages of a plurality of memory cells has degraded.

For example, the control logic circuit 150 may perform an OVS operation on a relatively smaller range as the extent to which the threshold voltage distribution of a plurality of memory cells has degraded increases.

As a result, the non-volatile memory device 100 according to example embodiments may improve the accuracy of an operation to estimate a valley in the distribution. For example, the non-volatile memory device 100 may improve the performance of an operation to determine a read voltage for a plurality of memory cells.

Referring to FIGS. 1, 8A, and 8B, the control logic circuit 150 according to some example embodiments may perform an additional OVS operation based on a default voltage Vdef when the difference between the first estimated voltage Ve1 and the default voltage Vdef is less than or equal to the second threshold value. For example, the control logic circuit 150 may apply the default voltage Vdef as the wordline voltage VWL when the difference between the first estimated voltage Ve1 and the default voltage Vdef is less than or equal to the second threshold value. For example, the default voltage Vdef may be applied to a plurality of memory cells through at least a portion of the wordlines WLs.

According to some example embodiments, the control logic circuit 150 may change the develop period to perform an OVS operation when the difference between the first estimated voltage Ve1 and the default voltage Vdef is less than or equal to the second threshold value.

For example, the control logic circuit 150 may perform a develop operation during a second develop period (i.e., a 2nd develop period) smaller than the first develop period when the difference between the first estimated voltage Ve1 and the default voltage Vdef is less than or equal to the second threshold value.

The second develop period may be maintained for a second develop time tb, shorter than the first develop time ta of the first develop period and the re-develop period (see FIGS. 7A and 7B).

For example, the control logic circuit 150 may perform an additional OVS operation relative to the default voltage Vdef based on the second develop period when the difference between the first estimated voltage Ve1 and the default voltage Vdef is less than or equal to the second threshold value.

For example, the control logic circuit 150 may precharge a sensing voltage VSO at a sense node SO to the power supply voltage VDD in response to a first sensing period included in the first OVS operation coming to an end.

For example, the control logic circuit 150 may control at least one transistor (for example, the first PMOS transistor P1) connected to the sense node SO to precharge the sensing voltage VSO to the power supply voltage VDD during the precharge period (e.g., see FIG. 5B).

Furthermore, the control logic circuit 150 may perform a develop operation during the second develop period. For example, the control logic circuit 150 may develop the first bitline BL1 during the second develop period smaller than the first develop period.

The second develop period may be understood as having a shorter time interval than the first develop period.

For example, the control logic circuit 150 may control at least one transistor (for example, the first transistor M1) connected to the sense node SO such that the sensing voltage VSO, precharged to the power supply voltage VDD, is discharged through the first bitline BL1 during the second develop period (e.g., see FIG. 5B).

Referring to FIG. 8A, when the difference between the first estimated voltage Ve1 and the default voltage Vdef is greater than the third threshold value, the control logic circuit 150 may apply a fourth reset signal RST4 to the latch circuit 540 within the second develop period (e.g., see FIG. 5B).

The third threshold value may be understood as being smaller than both the first threshold value Vth1 and the second threshold value.

For example, the second threshold value may be 200 mV, the first threshold value may be 300 mV, and the third threshold value may be 100 mV. However, these are merely examples and the threshold values are not limited thereto.

When the difference between the first estimated voltage Ve1 and the default voltage Vdef is greater than the third threshold value, the control logic circuit 150 may apply a fourth reset signal RST4 to the first page buffer group PBG1 within the second develop period.

Also, the control logic circuit 150 may apply the fourth reset signal RST4 to the second page buffer group PBG2 within a develop period smaller than the second develop period.

The control logic circuit 150 may apply a fourth set signal SET4 to the latch circuit 540 after a fourth time t4 from a time point at which the fourth reset signal RST4 is applied.

For example, the fourth time t4 may be understood as having a value corresponding to half of the fourth range, which is larger than the second range R2. For example, the fourth time t4 may be referred to as a relatively longer time compared to the second time t2 (see FIG. 7A).

The fourth range may be understood as being larger than the second range R2 and smaller than the first range R1.

The control logic circuit 150 may count the number of memory cells having a threshold voltage within a range corresponding to the fourth time t4 based on the state data stored at a time point at which each of the fourth reset signal RST4 and the fourth set signal SET4 is applied.

For example, the control logic circuit 150 may count the number of memory cells having a threshold voltage lower than or equal to the default voltage Vdef in the fourth range based on the state data stored at a time point at which each of the fourth reset signal RST4 and the fourth set signal SET4 is applied.

Also, the control logic circuit 150 may perform an operation, which is substantially the same as the operation to obtain the number of memory cells having a threshold voltage lower than or equal to the default voltage Vdef in the fourth range, to obtain the number of memory cells having a threshold voltage higher than the default voltage Vdef.

For example, the control logic circuit 150 may apply a reset signal and a set signal having an interval of a fourth time t4 to the latch circuit 540. For example, the reset signal and the set signal may be output in synchronization with a rising edge of a clock signal, which are different from a rising edge at a time point at which the fourth reset signal RST4 and the fourth set signal SET4 are applied to the clock signal.

As a result, the control logic circuit 150 may count the number of memory cells having a threshold voltage higher than the default voltage Vdef in the fourth range.

Furthermore, the control logic circuit 150 may obtain (or determine) the voltage estimated as a valley in distributions of the threshold voltages of a plurality of memory cells based on a result of the count. The operation to obtain the voltage estimated as a valley in the distributions of the threshold voltages of the plurality of memory cells may be referred to as a fourth OVS operation.

Furthermore, the control logic circuit 150 may perform a compensation operation based on the voltage estimated as the valley in the distributions of the threshold voltages of the plurality of memory cells.

For example, the control logic circuit 150 may perform an operation including a compensation-precharge period (C-Precharge period), a compensation-develop period (C-Develop period), and a compensation-sense period (C-Sense period) based on the result of the fourth OVS operation.

For example, the control logic circuit 150 may control at least one transistor (for example, the first PMOS transistor P1) connected to the sense node SO to precharge the sensing voltage VSO to the power supply voltage VDD during the compensation-precharge period (C-precharge period) (e.g., see FIG. 5B).

Also, the control logic circuit 150 may perform a develop operation on the first bitline BL1 during the compensation-develop period (C-develop period) having a length corresponding to the estimated voltage determined through the fourth OVS operation.

Also, the control logic circuit 150 may apply a set signal to the latch circuit 540 within the compensation-sense period (C-sense period) such that the latch circuit 540 stores state data.

Referring to FIG. 8B, when the difference between the first estimated voltage Ve1 and the default voltage Vdef is less than or equal to a third threshold value, the control logic circuit 150 may apply a fifth reset signal RST5 to the latch circuit 540 within the second develop period (e.g., see FIG. 5B).

For example, when the difference between the first estimated voltage Ve1 and the default voltage Vdef is less than or equal to the third threshold value, the control logic circuit 150 may apply the fifth reset signal RST5 to the first page buffer group PBG1 within the second develop period.

Also, the control logic circuit 150 may apply the fifth reset signal RST5 to the second page buffer group PBG2 within a develop period smaller than the second develop period.

However, the re-develop period (i.e., 2nd develop period) illustrated in FIG. 8B may be relatively shorter compared to the re-develop period illustrated in FIG. 8A. For example, the greater the difference between the first estimated voltage Ve1 and the default voltage Vdef, the longer the bitline may be developed.

The control logic circuit 150 may apply a fifth set signal SET5 to the latch circuit 540 after a fifth time t5 from a time point at which the fifth reset signal RST5 is applied.

For example, the fifth time t5 may be understood as having a value corresponding to half of the fifth range, which is larger than the fourth range.

Also, the fifth range may be understood as being larger than the fourth range and smaller than the first range R1.

The control logic circuit 150 may count the number of memory cells having a threshold voltage within a range corresponding to the fifth time t5 based on the state data stored at a time point at which each of the fifth reset signal RST5 and the fifth set signal SET5 is applied.

For example, the control logic circuit 150 may count the number of memory cells having a threshold voltage lower than or equal to the default voltage Vdef in the fifth range based on the state data stored at a time point at which each of the fifth reset signal RST5 and the fifth set signal SET5 is applied.

Furthermore, the control logic circuit 150 may perform an operation, which is substantially the same as the operation to obtain the number of memory cells having a threshold voltage lower than or equal to the default voltage Vdef in the fifth range to obtain the number of memory cells having a threshold voltage higher than the default voltage Vdef.

For example, the control logic circuit 150 may apply a reset signal and a set signal having an interval of a fifth time t5 to the latch circuit 540. For example, the reset signal and the set signal may be output in synchronization with a rising edge of a clock signal, which are different from a rising edge at which a time point at which the fifth reset signal RST5 and the fifth set signal SET5 are applied, to the clock signal.

As a result, the control logic circuit 150 may count the number of memory cells having a threshold voltage higher than the default voltage Vdef in the fifth range.

Furthermore, the control logic circuit 150 may obtain (or determine) the voltage estimated as a valley in the distributions of the threshold voltages of the plurality of memory cells, based on a result of the count. The operation to obtain the voltage estimated as the valley in the distributions of the threshold voltages of the plurality of memory cells may be referred to as a fifth OVS operation.

Furthermore, the control logic circuit 150 may perform a compensation operation based on the voltage estimated as the valley in the distributions of the threshold voltages of the plurality of memory cells.

For example, the control logic circuit 150 may perform an operation including a compensation-precharge period (C-Precharge period), a compensation-develop period (C-Develop period), and a compensation-sense period (C-Sense period) based on the result of the fifth OVS operation.

For example, the control logic circuit 150 may control at least one transistor (for example, the first PMOS transistor P1) connected to the sense node SO to precharge the sensing voltage VSO to the power supply voltage VDD during the compensation-precharge period (C-precharge period) (e.g., see FIG. 5B).

Also, the control logic circuit 150 may perform a develop operation on the first bitline BL1 during the compensation-develop period (C-develop period) having a length corresponding to the estimated voltage determined through the fifth OVS operation.

Also, the control logic circuit 150 may apply the set signal to the latch circuit 540 within the compensation-sense period (C-sense period) such that the latch circuit 540 stores state data.

Referring to the above-described configuration, the control logic circuit 150 may change the develop period without changing the wordline voltage VWL to perform an OVS operation when the difference between the default voltage Vdef and the first estimated voltage Ve1 is less than or equal to the second threshold value.

For example, when the difference between the default voltage Vdef and the first estimated voltage Ve1 is less than or equal to a second threshold value, the control logic circuit 150 may omit a wordline set-up period (e.g., see the WL setup period in FIGS. 7A and 7B) during which the wordline voltage VWL is changed.

Accordingly, the control logic circuit 150 may complete the plurality of OVS operations in a relatively shorter time, compared to the case in which the wordline voltage VWL is changed, when the difference between the default voltage Vdef and the first estimated voltage Ve1 is less than or equal to the second threshold value.

As a result, the non-volatile memory device 100 according to example embodiments may reduce the time required to determine a read voltage for a plurality of memory cells.

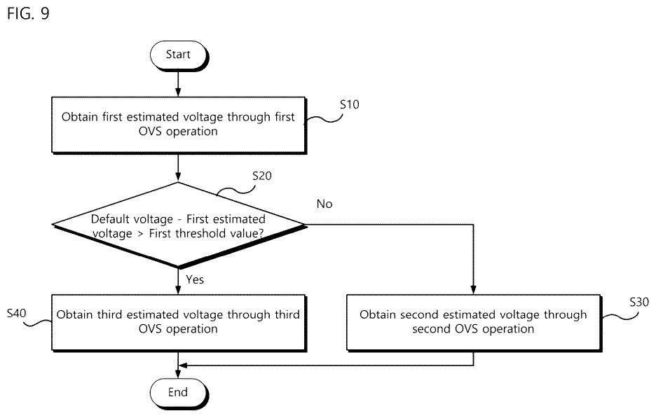

FIG. 9 is a flowchart illustrating a method of operating a non-volatile memory device according to some example embodiments.

Referring to FIGS. 1 and 9, the control logic circuit 150 or the non-volatile memory device 100 according to some example embodiments may perform at least two OVS operations to determine a read voltage for a plurality of memory cells.

In operation S10, the control logic circuit 150 according to some example embodiments may obtain a first estimated voltage Ve1 through a first OVS operation.

For example, the control logic circuit 150 may perform a first OVS operation on a first range R1 relative to a predetermined default voltage Vdef (e.g., see FIG. 3).

For example, the default voltage Vdef may be understood as a voltage set for a read operation during an initial program operation of the plurality of memory cells. For example, the default voltage Vdef may be understood as a voltage corresponding to a valley in the distribution of threshold voltages of the plurality of memory cells during the initial program operation of the memory cell array 110.

Also, the first range R1 may be understood as a range between two voltage levels having a predetermined difference from the default voltage Vdef centered around the default voltage Vdef.

The control logic circuit 150 may obtain (or determine) a first estimated voltage Ve1 estimated as a valley in the distribution of the threshold voltages of the plurality of memory cells, based on the number of memory cells having a threshold voltage within the first range R1 relative to the default voltage Vdef.

For example, the control logic circuit 150 may determine the first estimated voltage Ve1 from the number of memory cells having a threshold voltage within the first range R1 based on a predetermined equation.

Also, the control logic circuit 150 may perform an OVS operation based on the first estimated voltage Ve1 obtained through the first OVS operation.

In operation S20, the control logic circuit 150 according to some example embodiments may determine whether a difference between the first estimated voltage Ve1 and the default voltage Vdef is greater than a predetermined first threshold value Vth1. As used herein, “a difference between a value X and a value Y” (or similar language) may refer to an absolute value of a difference (i.e., an absolute difference) between the value X and the value Y, unless the context clearly indicates otherwise.

For example, the first threshold value Vth1 may be 300 mV, but example embodiments are not limited thereto.

The difference between the first estimated voltage Ve1 and the default voltage Vdef may be understood as indicating the extent to which the distribution of the threshold voltages of the plurality of memory cells has degraded.

In operation S30, the control logic circuit 150 may obtain a second estimated voltage through a second OVS operation.

For example, the control logic circuit 150 may perform a second OVS operation on a second range R2 smaller than the first range R1 relative to the first estimated voltage Ve1 when the difference between the first estimated voltage Ve1 and the default voltage Vdef is less than or equal to the predetermined first threshold value (e.g., see FIG. 4A).

For example, the control logic circuit 150 may apply the first estimated voltage Ve1 through a wordline and count the number of memory cells having a threshold voltage within the second range R2 while the first estimated voltage Ve1 is applied.

Also, the control logic circuit 150 may obtain the second estimated voltage based on a result of the count.

In operation S40, the control logic circuit 150 may obtain a third estimated voltage through a third OVS operation.

For example, when the difference between the first estimated voltage Ve1 and the default voltage Vdef is greater than the first threshold value, a third OVS operation may be performed on a third range R3 smaller than the second range R2 relative to the first estimated voltage Ve1 (e.g., see FIG. 4B).

For example, the control logic circuit 150 may apply the first estimated voltage Ve1 through a wordline and count the number of memory cells having a threshold voltage within the third range R3 while the first estimated voltage Ve1 is applied.

Also, the control logic circuit 150 may obtain the third estimated voltage based on a result of the count.

In some example embodiments, the control logic circuit 150 may store the difference between the first estimated voltage Ve1 and the default voltage Vdef and a range of the OVS operation corresponding to the difference.

For example, the control logic circuit 150 may divide the difference between the first estimated voltage Ve1 and the default voltage Vdef into a plurality of intervals and store data including a range of the OVS operation corresponding to each of the intervals in the form of a table (for example, a lookup table).

Furthermore, the control logic circuit 150 may determine an estimated voltage (for example, a second estimated voltage or a third estimated voltage), obtained through a plurality of OVS operations, as a read voltage for the memory cell array 110.

For example, the control logic circuit 150 may apply the estimated voltage (for example, the second estimated voltage or the third estimated voltage), obtained through the plurality of OVS operations, to at least a portion of the wordlines WLs during a read operation.

Referring to the above configuration, the control logic circuit 150 may perform an OVS operation on a smaller range relative to the first estimated voltage Ve1, as the difference between the first estimated voltage Ve1 and the default voltage Vdef increases, based on a result of the first OVS operation.

For example, the control logic circuit 150 may perform an additional OVS operation on a relatively smaller range as the extent to which the distribution of threshold voltages of the plurality of memory cells has degraded increases.

As a result, the non-volatile memory device 100 according to example embodiments may improve the accuracy of an operation to estimate a valley in the distribution. For example, the non-volatile memory device 100 may improve the performance of an operation to determine a read voltage for a plurality of memory cells.

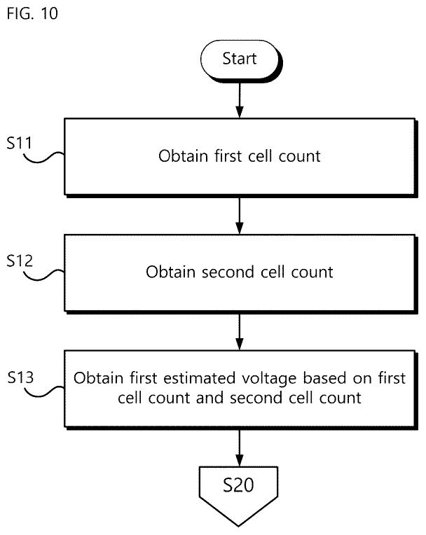

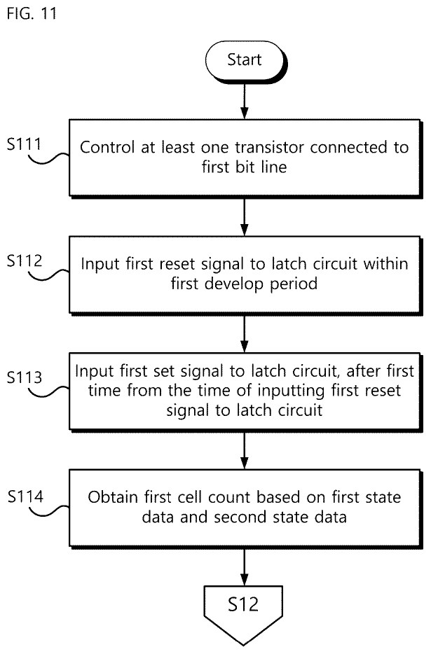

FIG. 10 is a flowchart illustrating a method of obtaining a first estimated voltage by a control logic circuit according to some example embodiments. FIG. 11 is a flowchart illustrating a method of obtaining a first cell count by a control logic circuit according to some example embodiments.

Referring to FIGS. 1 and 10, the control logic circuit 150 according to some example embodiment may obtain a first estimated voltage Ve1 through an OVS operation on the first range R1 relative to a default voltage Vdef (e.g., see FIG. 3).

For example, the control logic circuit 150 may determine the first estimated voltage Ve1 relative to the number of memory cells (# of cells) having a threshold voltage Vt within the first range R1 based on the default voltage Vdef.

In operation S11, the control logic circuit 150 according to some example embodiments may obtain a first cell count CC1.

For example, the control logic circuit 150 may obtain the first cell count CC1 by counting the number of memory cells (# of cells) having a threshold voltage Vt lower than or equal to the default voltage Vdef, among the memory cells having a threshold voltage Vt within the first range R1 (e.g., see FIG. 3).

Referring to FIGS. 1, 10, and 11, the control logic circuit 150 according to some example embodiments may control a first page buffer PB1 to count the first cell count CC1 (e.g., see FIGS. 3 and 5B).

In operation S111, the control logic circuit 150 according to some example embodiments may control at least one transistor (for example, a first transistor M1) connected to a first bitline BL1 (e.g., see FIG. 5B).

For example, the control logic circuit 150 may perform a develop operation during a first develop period. For example, the control logic circuit 150 may develop the first bitline BL1 during the first develop period.

For example, the control logic circuit 150 may control at least one transistor (for example, a first transistor M1) connected to the first bitline BL1 such that a sensing voltage VSO, precharged to a power supply voltage VDD, is discharged through the first bitline BL1 during the first develop period (e.g., see FIGS. 5B, 7A, 7B, 8A, and 8B).

In operation S112, the control logic circuit 150 according to some example embodiments may apply (i.e., may input) a first reset signal RST1 to the latch circuit 540 within the first develop period (e.g., see FIGS. 5B, 7A, 7B, 8A, and 8B).

For example, the control logic circuit 150 may apply a first reset signal RST1 to the latch circuit 540 such that the latch circuit 540 stores first state data of memory cells connected to the first bitline BL1 within the first develop period.

In operation S113, the control logic circuit 150 according to some example embodiments may apply a first set signal SET1 to the latch circuit 540 (e.g., see FIGS. 5B, 7A, 7B, 8A, and 8B).

For example, the control logic circuit 150 may apply a first set signal SET1 to the latch circuit 540 such that the latch circuit 540 (or the first page buffer PB1) stores second state data of memory cells connected to the first bitline BL1.

The control logic circuit 150 may apply the first set signal SET1 to the latch circuit 540 after a first time t1 from a time point at which the first reset signal RST1 is applied to the latch circuit 540.

For example, the first time t1 may be understood as having a value corresponding to half of the first range R1.

In operation S114, the control logic circuit 150 according to some example embodiments may obtain the first cell count CC1 based on the first state data and the second state data.

For example, the control logic circuit 150 may obtain the first cell count CC1 corresponding to the number of memory cells having a threshold voltage within a range corresponding to a first time t1 based on the first state data and the second state data.

In operation S12, the control logic circuit 150 according to some example embodiments may obtain a second cell count CC2.

For example, the control logic circuit 150 may obtain the second cell count CC2 by counting the number of memory cells (# of cells) having a threshold voltage Vt higher than the default voltage Vdef, among the memory cells having a threshold voltage Vt within the first range R1 (e.g., see FIG. 3).

In operation S13, the control logic circuit 150 may obtain (or determine) a first estimated voltage Ve1 based on the first cell count CC1 and the second cell count CC2.

For example, the control logic circuit 150 may obtain (or determine) the first estimated voltage Ve1 estimated as a valley in distributions of threshold voltages of a plurality of memory cells based on a difference between the first cell count CC1 and the second cell count CC2.

For example, the control logic circuit 150 may obtain the first estimated voltage Ve1 from the first cell count CC1 and the second cell count CC2 based on a prestored equation (for example, Equation 1 of FIG. 3).

Information (or data) on the equation and a value of each coefficient included in the equation may be stored in the non-volatile memory device 100.

For example, the control logic circuit 150 may obtain the first estimated voltage Ve1 by performing a first OVS operation based on the predetermined default voltage Vdef and the first range R1.

Referring to the above configuration, the control logic circuit 150 may perform an OVS operation using a predetermined equation without storing a table corresponding to the extent to which the distribution of the threshold voltages of the memory cells has degraded.

As a result, the non-volatile memory device 100 according to example embodiments may improve the accuracy of the OVS operation compared to the case of storing a table corresponding to the extent to which the distribution of the threshold voltages of the memory cells has degraded.

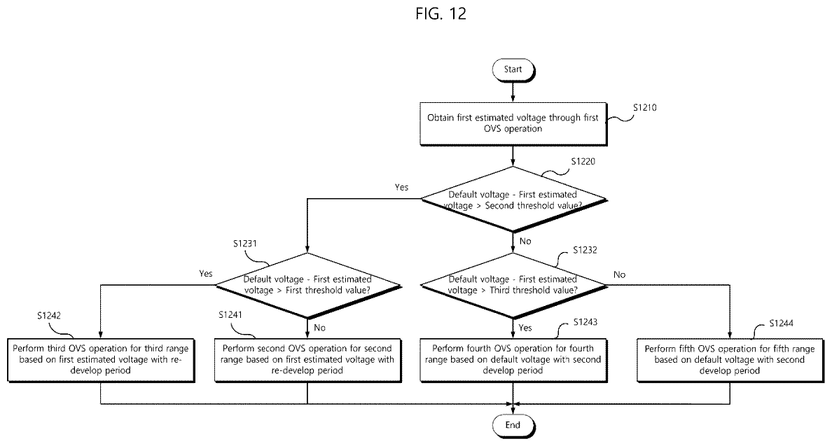

FIG. 12 is a flowchart illustrating a method of controlling a first page buffer to perform an OVS operation by a control logic circuit based on a magnitude of a difference between a first estimated voltage and a reference voltage, according to some example embodiments.

Referring to FIGS. 1 and 12, the control logic circuit 150 according to some example embodiments may change the magnitude of the wordline voltage VWL (e.g., see FIGS. 7A and 7B) or change the length of the develop period (e.g., see FIGS. 8A and 8B) depending on whether the first estimated voltage Ve1 is higher than the second threshold value.

In operation S1210, the control logic circuit 150 according to some example embodiments may obtain the first estimated voltage Ve1 through a first OVS operation. For example, the control logic circuit 150 may perform a first OVS operation on the first range R1 relative to the predetermined default voltage Vdef (e.g., see FIG. 3).

Operation S1210 may be understood as being substantially the same as operation S10 illustrated in FIG. 9. Therefore, redundant descriptions will be omitted to avoid repeated description.

In operation S1220, the control logic circuit 150 according to some example embodiments may determine whether the difference between the first estimated voltage Ve1 and the default voltage Vdef is greater than a predetermined second threshold value.

For example, the second threshold value may be 200 mV, but example embodiments are not limited thereto.

In operation S1231, the control logic circuit 150 may determine whether the difference between the first estimated voltage Ve1 and the default voltage Vdef is greater than a predetermined first threshold value Vth1.

The first threshold value Vth1 may be understood as being larger than the second threshold value. For example, the first threshold value Vth1 may be 300 mV, but example embodiments are not limited thereto.

Also, the difference between the first estimated voltage Ve1 and the default voltage Vdef may be understood as indicating the extent to which the distribution of the threshold voltages of the plurality of memory cells has degraded.

In operation S1241, the control logic circuit 150 may obtain a second estimated voltage through a second OVS operation.

For example, when the difference between the first estimated voltage Ve1 and the default voltage Vdef is less than or equal to the first threshold value Vth1, the control logic circuit 150 may perform the second OVS operation on a second range R2 smaller than the first range R1 relative to the first estimated voltage Ve1 (e.g., see FIG. 4A).

According to some example embodiments, when the difference between the first estimated voltage Ve1 and the default voltage Vdef is less than or equal to the first threshold value Vth1, the control logic circuit 150 may apply a second reset signal RST2 to the latch circuit 540 within a re-develop period (e.g., see FIGS. 5B and 7A).

The re-develop period may be understood as having substantially the same time interval as the first develop period during which the first OVS operation was performed.

The control logic circuit 150 may apply a second set signal SET2 to the latch circuit 540 after a second time t2 from a time point at which the second reset signal RST2 is applied (e.g., see FIGS. 5B and 7A).

For example, the second time t2 may be understood as having a value corresponding to half of the second range R2.

The control logic circuit 150 may count the number of memory cells (for example, third cell count CC3) having a threshold voltage within a range corresponding to the second time t2 based on state data stored at a time point at which each of the second reset signal RST2 and the second set signal SET2 is applied.

Also, the control logic circuit 150 may obtain a fourth cell count CC4 by performing substantially the same operation as the operation to obtain the third cell count CC3 (e.g., see FIG. 4A).

For example, the control logic circuit 150 may apply a reset signal and a set signal having an interval of a second time t2 to the latch circuit 540.

As a result, the control logic circuit 150 may obtain a fourth cell count CC4 corresponding to the number of memory cells (# of cells) having a threshold voltage Vt higher than the first estimated voltage Ve1 in the second range R2.

Furthermore, the control logic circuit 150 may obtain (or determine) a second estimated voltage estimated as a valley in the distributions of the threshold voltages of the plurality of the memory cells, based on the third cell count CC3 and the fourth cell count CC4.

In operation S1242, the control logic circuit 150 may obtain a third estimated voltage through a third OVS operation.

For example, when the difference between the first estimated voltage Ve1 and the default voltage Vdef is greater than the first threshold value, the third OVS operation may be performed on a third range R3 smaller than the second range R2 relative to the first estimated voltage Ve1 (e.g., see FIG. 4B).

According to some example embodiments, when the difference between the first estimated voltage Ve1 and the default voltage Vdef is greater than the first threshold value Vth1, the control logic circuit 150 may apply a third reset signal RST3 to the latch circuit 540 within a re-develop period (e.g., see FIGS. 5B and 7B).

The control logic circuit 150 may apply a third set signal SET3 to the latch circuit 540 after a third time t3 from a time point at which the third reset signal RST3 is applied (e.g., see FIGS. 5B and 7B).

For example, the third time t3 may be understood as having a value corresponding to half of the third range R3 smaller than the second range R2.

The control logic circuit 150 may count the number of memory cells (for example, fifth cell count CC5) having a threshold voltage within a range corresponding to the third time t3, based on state data stored at a time point at which each of the third reset signal RST3 and the third set signal SET3 is applied.

Also, the control logic circuit 150 may obtain a sixth cell count CC6 by performing substantially the same operation as the operation to obtain the fifth cell count CC5 (e.g., see FIG. 4B).

For example, the control logic circuit 150 may apply a reset signal and a set signal having an interval of a third time t3 to the latch circuit 540. Thus, the control logic circuit 150 may obtain a sixth cell count CC6 corresponding to the number of memory cells (# of cells) having a threshold voltage Vt higher than the first estimated voltage Ve1 in the third range R3.

Furthermore, the control logic circuit 150 may obtain (or determine) a third estimated voltage estimated as a valley in the distributions of the threshold voltages of the plurality of the memory cells based on the fifth cell count CC5 and the sixth cell count CC6.

Referring to the above configuration, the control logic circuit 150 may perform an OVS operation on a smaller range (for example, the third range R3) relative to the first estimated voltage Ve1, based on a result of the first OVS operation, as the difference between the first estimated voltage Ve1 and the default voltage Vdef increases.

As a result, the non-volatile memory device 100 according to example embodiments may improve the accuracy of an operation to estimate a valley in the distribution. For example, the non-volatile memory device 100 may improve the performance of an operation to determine a read voltage for a plurality of memory cells.

The control logic circuit 150 according to some example embodiments may perform additional OVS operations based on the default voltage Vdef when a difference between the first estimated voltage Ve1 and the default voltage Vdef is less than or equal to a second threshold value.

According to some example embodiments, the control logic circuit 150 may perform an OVS operation by changing the develop period when the difference between the first estimated voltage Ve1 and the default voltage Vdef is less than or equal to the second threshold value.

For example, the control logic circuit 150 may perform a develop operation for a second develop period, smaller than the first develop period, when the difference between the first estimated voltage Ve1 and the default voltage Vdef is less or equal to than the second threshold value.

For example, when the difference between the first estimated voltage Ve1 and the default voltage Vdef is less than or equal to the second threshold value, the control logic circuit 150 may perform an additional OVS operation based on the second develop period relative to the default voltage Vdef.

In operation S1232, the control logic circuit 150 may determine whether the difference between the first estimated voltage Ve1 and the default voltage Vdef is greater than a predetermined third threshold value.

The third threshold value may be understood as being smaller than both the first and second threshold values. For example, the third threshold value may be 100 mV, but example embodiments are not limited thereto.

For example, the control logic circuit 150 may determine whether the difference between the first estimated voltage Ve1 and the default voltage Vdef is greater than the predetermined third threshold value, when the difference between the first estimated voltage Ve1 and the default voltage Vdef is less than or equal to the second threshold value.

In operation S1243, the control logic circuit 150 may perform a fourth OVS operation on a fourth range relative to the default voltage Vdef, based on the second develop period. The fourth range may be understood as a larger range than the second range R2.

For example, the control logic circuit 150 may perform a fourth OVS operation on a fourth range relative to the default voltage Vdef, based on the second develop period, when the difference between the first estimated voltage Ve1 and the default voltage Vdef is greater than the third threshold value.

According to some example embodiments, when the difference between the first estimated voltage Ve1 and the default voltage Vdef is greater than the third threshold value, the control logic circuit 150 may apply a fourth reset signal RST4 to the latch circuit 540 within the second develop period (e.g., see FIGS. 5B and 8A).

Also, the control logic circuit 150 may apply the fourth set signal SET4 to the latch circuit 540 after a fourth time t4 from a time point at which the fourth reset signal RST4 is applied (e.g., see FIGS. 5B and 8A).

For example, the fourth time t4 may be understood as having a value corresponding to half of the fourth range. For example, the fourth time t4 may be referred to as a relatively longer time compared to the second time t2.

The control logic circuit 150 may count the number of memory cells having a threshold voltage within a range corresponding to the fourth time t4, based on state data stored at a time at which each of the fourth reset signal RST4 and the fourth set signal SET4 is applied.

Also, the control logic circuit 150 may perform substantially the same operation as the operation to obtain the number of memory cells having a threshold voltage lower than or equal to the default voltage Vdef in the fourth range, thereby obtaining the number of memory cells having a threshold voltage higher than the default voltage Vdef.

Furthermore, the control logic circuit 150 may obtain (or determine) a voltage estimated as a valley in the distributions of the threshold voltages of the plurality of memory cells, based on a result of the count.

In operation S1244, the control logic circuit 150 may perform a fifth OVS operation on a fifth range relative to the default voltage Vdef, based on the second develop period.

For example, when the difference between the first estimated voltage Ve1 and the default voltage Vdef is less than or equal to the third threshold value, the control logic circuit 150 may perform the fifth OVS operation on a fifth range relative to the default voltage Vdef, based on the second develop period.

The fifth range may be understood as a larger range than the fourth range.

According to some example embodiments, when the difference between the first estimated voltage Ve1 and the default voltage Vdef is less than or equal to the third threshold value, the control logic circuit 150 may apply a fifth reset signal RST5 to the latch circuit 540 within the second develop period (e.g., see FIGS. 5B and 8B).

Also, the control logic circuit 150 may apply the fifth set signal SET5 to the latch circuit 540 after a fifth time t5 from a time point at which the fifth reset signal RST5 is applied (e.g., see FIGS. 5B and 8B).

For example, the fifth time t5 may be understood as having a value corresponding to half of the fifth range.

The control logic circuit 150 may count the number of memory cells having a threshold voltage within a range corresponding to the fifth time t5, based on the state data stored at a time point at which each of the fifth reset signal RST5 and the fifth set signal SET5 is applied.

Also, the control logic circuit 150 may perform substantially the same operation as the operation to obtain the number of memory cells having a threshold voltage lower than or equal to the default voltage Vdef in the fifth range, thereby obtaining the number of memory cells having a threshold voltage higher than the default voltage Vdef.

Furthermore, the control logic circuit 150 may obtain (or determine) a voltage estimated as a valley in the distributions of the threshold voltages of the plurality of memory cells, based on a result of the count.

Referring to the above configuration, the control logic circuit 150 may perform an OVS operation by changing the develop period without changing the wordline voltage VWL when the difference between the default voltage Vdef and the first estimated voltage Ve1 is less than or equal to the second threshold value (e.g., see FIGS. 8A and 8B).

For example, when the difference between the default voltage Vdef and the first estimated voltage Ve1 is less than or equal to the second threshold value, the control logic circuit 150 may omit the wordline set-up period (e.g., see a WL setup period in FIGS. 7A and 7B) during which the wordline voltage VWL is changed.

Accordingly, when the difference between the default voltage Vdef and the first estimated voltage Ve1 is less than or equal to the second threshold value, the control logic circuit 150 may complete the additional OVS operation in a relatively shorter time compared to the case in which the wordline voltage VWL is changed.

As a result, the non-volatile memory device 100 according to example embodiments may reduce the time required to determine the read voltage for a plurality of memory cells.

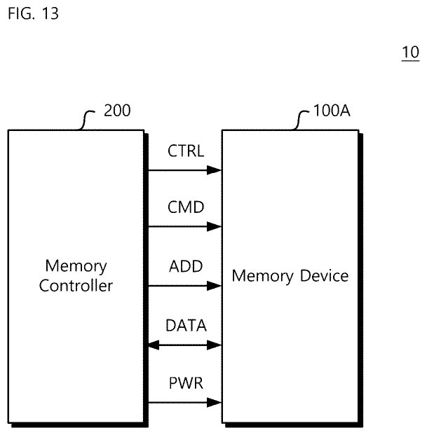

FIG. 13 is a block diagram illustrating a memory system including a memory controller and a memory device, according to some example embodiments.

Referring to FIG. 13, a memory system 10 according to some example embodiments may include a memory controller 200 and a memory device 100A.

The memory device 100A illustrated in FIG. 13 may be understood as an example implementation of the non-volatile memory device 100 illustrated in FIG. 1. For example, the memory device 100A illustrated in FIG. 13 may be understood to have substantially the same configuration as the non-volatile memory device 100 illustrated in FIG. 1.

Therefore, redundant descriptions of substantially the same configuration will be omitted to avoid repeated description.

According to some example embodiments, the memory controller 200 and the memory device 100A may be provided as a single chip, a single package, or a single module. Also, the memory controller 200 and the memory device 100A may be mounted based on various packages and provided as a storage device such as a memory card.

The memory device 100A may perform erase, write, and/or read operations under the control of the memory controller 200. For example, the memory controller 200 may store data DATA in the memory device 100A and may read data DATA stored in the memory device 100A. To this end, the memory device 100A may receive a command CMD, an address ADD, and data DATA through input/output lines. Also, the memory device 100A may receive a controller control signal CTRL through a control line. In addition, the memory device 100A may be supplied with power PWR from the memory controller 200.

Memory cells included in the memory device 100A have a physical characteristic in which a threshold voltage distribution changes due to factors such as program elapsed time, temperature, program disturbance, or read disturbance. For example, errors may occur in data stored in the memory device 100A due to the above-mentioned factors. The memory system 10 may employ various error correction techniques to correct such errors.

According to some example embodiments, the memory device 100A may perform a first OVS operation on a first range R1 based on a predetermined default voltage Vdef with respect to the distribution of threshold voltages of a plurality of memory cells (e.g., see FIG. 3).

For example, the default voltage Vdef may be understood as a voltage set for a read operation during an initial program operation of the plurality of memory cells. For example, the default voltage Vdef may be understood as a voltage corresponding to a valley in the distribution of the threshold voltages of the plurality of memory cells during the initial program operation of the memory cell array 110 (see FIG. 1).

In addition, the first range R1 may be understood as a range between two voltage levels having a predetermined difference from the default voltage Vdef, centered around the default voltage Vdef.

The memory device 100A may determine the number of memory cells (# of cells) having a threshold voltage Vt within the first range R1.

Furthermore, the memory device 100A may obtain (or determine) a first estimated voltage Ve1 estimated as a valley in the distribution of the threshold voltages of the plurality of memory cells, based on the number of memory cells (# of cells) having a threshold voltage Vt within the first range R1.

Also, the memory device 100A may perform an OVS operation based on the first estimated voltage Ve1 obtained through the first OVS operation.

For example, the memory device 100A may perform an additional OVS operation on a range smaller than the first range R1 relative to the first estimated voltage Ve1. The range of the additionally performed OVS operation may be determined by the magnitude of the difference (i.e., the absolute difference) between the first estimated voltage Ve1 and the default voltage Vdef.

For example, the memory device 100A may perform a second OVS operation on a second range smaller than the first range R1 relative to the first estimated voltage Ve1, when the difference between the first estimated voltage Ve1 and the default voltage Vdef is less than or equal to a predetermined first threshold value (e.g., see FIG. 4A). The memory device 100A may obtain a second estimated voltage through the second OVS operation.

For example, the memory device 100A may perform a third OVS operation on a third range smaller than the second range relative to the first estimated voltage Ve1, when the difference between the first estimated voltage Ve1 and the default voltage Vdef is greater than the first threshold value (e.g., see FIG. 4B). The memory device 100A may obtain a third estimated voltage through the third OVS operation.

Furthermore, the memory device 100A may determine an estimated voltage (for example, a second estimated voltage or a third estimated voltage), obtained through a plurality of OVS operations, as a read voltage for the memory cell array 110 (see FIG. 1).

For example, the memory device 100A may apply the estimated voltage (for example, the second estimated voltage or the third estimated voltage), obtained through the plurality of OVS operations, to at least a portion of wordlines WLs during a read operation.

Referring to the above configurations, the memory device 100A may perform an OVS operation on a smaller range relative to the first estimated voltage Ve1, as the difference between the first estimated voltage Ve1 and the default voltage Vdef increases, based on a result of the first OVS operation.

The difference between the first estimated voltage Ve1 and the default voltage Vdef may be understood as indicating the extent to which the distribution of the threshold voltages of the plurality of memory cells has degraded.

For example, the memory device 100A may perform an additional OVS operation on a relatively smaller range as the extent to which the distribution of the threshold voltages of the plurality of memory cells has degraded increases.

As a result, the non-volatile memory device 100 (and/or the memory system 10 including the memory device 100A) according to example embodiments may improve the accuracy of an operation to estimate a valley in the distribution. For example, the non-volatile memory device 100 may improve the performance of an operation to determine a read voltage for a plurality of memory cells.

As described above, the control logic circuit 150 according to example embodiments may perform an OVS operation on a smaller range relative to the first estimated voltage Ve1, as the difference between the first estimated voltage Ve1 and the default voltage Vdef increases, based on the result of the first OVS operation.

The difference between the first estimated voltage Ve1 and the default voltage Vdef may be understood as indicating the extent to which the distribution of the threshold voltages of the plurality of memory cells has degraded.

For example, the control logic circuit 150 may perform an OVS operation on a relatively smaller range as the extent to which the distribution of the threshold voltages of the plurality of memory cells has degraded increases.

As a result, the non-volatile memory device 100 according to example embodiments may improve the accuracy of an operation to estimate a valley in the distribution. For example, the non-volatile memory device 100 may improve the performance of an operation to determine a read voltage for a plurality of memory cells.

In addition, the control logic circuit 150 according to example embodiments may perform an OVS operation by changing a develop period without changing a wordline voltage VWL when the difference between the default voltage Vdef and the first estimated voltage Ve1 is less than or equal to a second threshold value.

For example, when the difference between the default voltage Vdef and the first estimated voltage Ve1 is less than or equal to the second threshold value, the control logic circuit 150 may omit a wordline set-up period during which the wordline voltage VWL is changed.

Accordingly, the control logic circuit 150 may complete the plurality of OVS operations in a relatively shorter time compared to the case in which the wordline voltage VWL is changed, when the difference between the default voltage Vdef and the first estimated voltage Ve1 is less than or equal to the second threshold value.

As a result, the non-volatile memory device 100 according to example embodiments may reduce the time required to determine the read voltage for the plurality of memory cells.

As set forth above, according to example embodiments, a non-volatile memory device may improve the performance of an operation to determine a read voltage for a plurality of memory cells.

While example embodiments have been shown and described above, it will be apparent to those skilled in the art that modifications and variations could be made without departing from the scope of the present inventive concepts as defined by the appended claims.

What is claimed is:

1. A non-volatile memory device comprising:
a memory cell array comprising a plurality of memory cells; and
a control logic circuit configured to determine a read voltage for the plurality of memory cells through an on-chip valley search (OVS) operation on a distribution of threshold voltages of the plurality of memory cells,
wherein the control logic circuit is configured to:
obtain a first estimated voltage through a first OVS operation on a first range of the distribution of threshold voltages, wherein the first range is relative to a default voltage;
obtain a second estimated voltage through a second OVS operation on a second range of the distribution of threshold voltages in response to an absolute difference between the first estimated voltage and the default voltage being less than or equal to a first threshold value, wherein the second range is smaller than the first range and is relative to the first estimated voltage; and
obtain a third estimated voltage through a third OVS operation on a third range of the distribution of threshold voltages in response to the absolute difference between the first estimated voltage and the default voltage being greater than the first threshold value, wherein the third range is smaller than the second range and is relative to the first estimated voltage.

2. The non-volatile memory device of claim 1, wherein the control logic circuit is configured to:
count a number of the memory cells having a threshold voltage within the first range that is less than or equal to the default voltage to obtain a first cell count;
count a number of the memory cells having a threshold voltage within the first range that is greater than the default voltage to obtain a second cell count; and
obtain the first estimated voltage from the first cell count and the second cell count based on a predefined equation.

3. The non-volatile memory device of claim 2, wherein the control logic circuit is configured to:
count a number of the memory cells having a threshold voltage within the second range that is less than or equal to the first estimated voltage to obtain a third cell count;
count a number of the memory cells having a threshold voltage within the second range that is greater than the first estimated voltage to obtain a fourth cell count; and
compare the third cell count and the fourth cell count to obtain the second estimated voltage.

4. The non-volatile memory device of claim 2, further comprising:
a page buffer circuit comprising a plurality of page buffers electrically connected to the plurality of memory cells through a plurality of bit lines,
wherein a first page buffer, among the plurality of page buffers, comprises:
a first PMOS transistor electrically connected between a power supply voltage and a sense node;
a second transistor electrically connected between the sense node and a first bit line among the plurality of bit lines; and
a latch circuit configured to store state data of ones of the plurality of memory cells that are electrically connected to the first bit line in response to a reset signal and a set signal received from the control logic circuit.

5. The non-volatile memory device of claim 4, wherein the control logic circuit is configured to:
control the first page buffer to develop the first bit line during a first develop period;
apply a first reset signal to the latch circuit such that the latch circuit stores first state data of the ones of the plurality of memory cells within the first develop period;
apply a first set signal to the latch circuit such that the latch circuit stores second state data of the ones of the plurality of memory cells, wherein the first set signal is applied after a time point at which the first reset signal is applied; and
obtain the first cell count based on the first state data and the second state data stored in the latch circuit.

6. The non-volatile memory device of claim 5, wherein, in response to the absolute difference between the first estimated voltage and the default voltage being greater than a second threshold value that is less than the first threshold value, the control logic circuit is configured to:
apply the first estimated voltage to at least one of the plurality of memory cells through a wordline;
turn on the first PMOS transistor to precharge the sense node to the power supply voltage; and
develop the first bit line during a re-develop period.

7. The non-volatile memory device of claim 6, wherein, in response to the absolute difference between the first estimated voltage and the default voltage being greater than the second threshold value and less than or equal to the first threshold value, the control logic circuit is configured to:
apply a second reset signal to the latch circuit within the re-develop period; and
apply a second set signal to the latch circuit after a time point at which the second reset signal is applied.

8. The non-volatile memory device of claim 6, wherein, in response to the absolute difference between the first estimated voltage and the default voltage being greater than the first threshold value, the control logic circuit is configured to:
apply a third reset signal to the latch circuit within the re-develop period; and
apply a third set signal to the latch circuit after a time point at which the third reset signal is applied.

9. The non-volatile memory device of claim 6, wherein, in response to the absolute difference between the first estimated voltage and the default voltage being less than or equal to the second threshold value, the control logic circuit is configured to:
apply the default voltage through the wordline;
turn on the first PMOS transistor to precharge the sense node to the power supply voltage; and
develop the first bit line during a second develop period that is shorter than the first develop period.

10. The non-volatile memory device of claim 9, wherein, in response to the absolute difference between the first estimated voltage and the default voltage being greater than a third threshold value and less than or equal to the second threshold value, the control logic circuit is configured to:
apply a fourth reset signal to the latch circuit within the second develop period; and
apply a fourth set signal to the latch circuit after a time point at which the fourth reset signal is applied.

11. The non-volatile memory device of claim 10, wherein, in response to the absolute difference between the first estimated voltage and the default voltage being less than or equal to the third threshold value, the control logic circuit is configured to:
apply a fifth reset signal to the latch circuit within the second develop period; and
apply a fifth set signal to the latch circuit after a time point at which the fifth reset signal is applied.

12. A method of operating a non-volatile memory device, the method comprising:
obtaining a first estimated voltage through a first on-chip valley search (OVS) operation on a first range of a distribution of threshold voltages of a plurality of memory cells, wherein the first range is relative to a default voltage;
obtaining a second estimated voltage through a second OVS operation on a second range of the distribution of threshold voltages in response to an absolute difference between the first estimated voltage and the default voltage being less than or equal to a first threshold value, wherein the second range is smaller than the first range and is relative to the first estimated voltage; and
obtaining a third estimated voltage through a third OVS operation on a third range of the distribution of threshold voltages in response to the absolute difference between the first estimated voltage and the default voltage being greater than the first threshold value, wherein the third range is smaller than the second range and is relative to the first estimated voltage.

13. The method of claim 12, wherein obtaining the first estimated voltage through the first OVS operation comprises:
counting a number of the memory cells having a threshold voltage within the first range that is less than or equal to the default voltage to obtain a first cell count;
counting a number of the memory cells having a threshold voltage within the first range that is greater than the default voltage to obtain a second cell count; and
obtaining the first estimated voltage from the first cell count and the second cell count using a predefined equation.

14. The method of claim 13, wherein obtaining the first cell count comprises:
controlling at least one transistor of the non-volatile memory device that is electrically connected to a first bit line to develop the first bit line during a first develop period;
inputting a first reset signal to a latch circuit of the non-volatile memory device within the first develop period such that the latch circuit stores first state data of ones of the plurality of memory cells that are electrically connected to the first bit line, wherein the latch circuit is electrically connected to a sense node;
inputting a first set signal to the latch circuit such that the latch circuit stores second state data of the ones of the plurality of memory cells, wherein the first set signal is input after a time point at which the first reset signal is input; and
obtaining the first cell count based on the first state data and the second state data stored in the latch circuit.

15. The method of claim 14, further comprising:
precharging the sense node in response to the absolute difference between the first estimated voltage and the default voltage being less than or equal to a second threshold value that is less than the first threshold value; and
controlling the at least one transistor to develop the first bit line during a second develop period that is shorter than the first develop period.

16. The method of claim 15, further comprising:
performing a fourth OVS operation on a fourth range of the distribution of threshold voltages based on the second develop period in response to the absolute difference between the first estimated voltage and the default voltage being less than or equal to the second threshold value and greater than a third threshold value, wherein the fourth range is larger than the second range and is relative to the default voltage; and
performing a fifth OVS operation on a fifth range of the distribution of threshold voltages based on the second develop period in response to the absolute difference between the first estimated voltage and the default voltage being less than or equal to the third threshold value, wherein the fifth range is larger than the fourth range and is relative to the default voltage.

17. A memory system comprising:
a memory device; and
a memory controller configured to store data in the memory device and read data stored in the memory device,
wherein the memory device comprises:
a memory cell array comprising a plurality of memory cells; and
a control logic circuit configured to determine read voltages of the plurality of memory cells through an on-chip valley search (OVS) operation on a distribution of threshold voltages of the plurality of memory cells, and
wherein the control logic circuit is configured to:
obtain a first estimated voltage through a first OVS operation on a first range of the distribution of threshold voltages, wherein the first range is relative to a default voltage;
obtain a second estimated voltage through a second OVS operation on a second range of the distribution of threshold voltages in response to an absolute difference between the first estimated voltage and the default voltage being less than or equal to a first threshold value, wherein the second range is smaller than the first range and is relative to the first estimated voltage; and
obtain a third estimated voltage through a third OVS operation on a third range of the distribution of threshold voltages in response to the absolute difference between the first estimated voltage and the default voltage being greater than the first threshold value, wherein the third range is smaller than the second range and is relative to the first estimated voltage.

18. The memory system of claim 17, wherein the control logic circuit is configured to:
count a number of the memory cells having a threshold voltage within the first range that is less than or equal to the default voltage to obtain a first cell count;
count a number of the memory cells having a threshold voltage within the first range that is greater than the default voltage to obtain a second cell count; and
obtain the first estimated voltage from the first cell count and the second cell count based on a predefined equation.

19. The memory system of claim 18, wherein the memory device further comprises a first page buffer electrically connected to at least a portion of the plurality of memory cells through a first bit line, and
wherein the first page buffer comprises:
a first PMOS transistor electrically connected between a power supply voltage and a sense node;
a second transistor electrically connected between the sense node and the first bit line; and
a latch circuit configured to store state data of ones of the plurality of memory cells that are electrically connected to the first bit line, based on a voltage level at the sense node.

20. The memory system of claim 19, wherein the control logic circuit is configured to:
apply a first reset signal to the latch circuit such that the latch circuit stores first state data of the ones of the plurality of memory cells within a first develop period;
apply a first set signal to the latch circuit such that the latch circuit stores second state data of the ones of the plurality of memory cells, wherein the first set signal is applied after a time point at which the first reset signal is applied; and
obtain the first cell count based on the first state data and the second state data stored in the latch circuit.
